(19) United States
(12) Patent Application Publication
(10) Pub. No.: US 2025/0299637 A1
(43) Pub. Date: Sep. 25, 2025

(54) ELECTRONIC DEVICE

(71) Applicant: InnoLux Corporation, Miao-Li County (TW)

(72) Inventors: Chandra LIUS, Miao-Li County (TW); Yu-Jhou GONG, Miao-Li County (TW); Yuan-Lin WU, Miao-Li County (TW); Kuan-Feng LEE, Miao-Li County (TW)

(21) Appl. No.: 19/063,675

(22) Filed: Feb. 26, 2025

(30) Foreign Application Priority Data
Mar. 22, 2024 (CN) 202410334368.5

(51) Int. Cl. G09G 3/3266

(52) U.S. Cl. CPC G09G 3/3266; G09G 2300/043; G09G 2310/062; G09G 2310/08; G09G 2360/14

(57) ABSTRACT

An electronic device includes a substrate, a first conductive layer, an electronic unit, a sensor unit and a sensor unit driving circuit. The first conductive layer is disposed on the substrate, and includes a first gate and a line segment connected to the first gate. The electronic unit and the sensor unit are disposed on the substrate. The sensor unit driving circuit is disposed on the substrate, and is electrically connected to the electronic unit and the sensor unit. The sensor driving circuit includes a first transistor with the first gate, and a shape of the first gate is different from a shape of the line segment.

### CROSS-REFERENCE TO RELATED APPLICATIONS

This application claims the benefits of the Chinese Patent Application Serial Number 202410334368.5, filed on Mar. 22, 2024, the subject matter of which is incorporated herein by reference.

### BACKGROUND

### Field of the Disclosure

The present disclosure relates to an electronic device and, more particularly, to an electronic device having a display function and a sensing function.

### Description of Related Art

In certain applications, electronic devices may need to have both display and sensing functions. However, currently, the display circuit and the sensor circuit are two independent sets of circuits, which take up a lot of space, resulting in low space utilization. Therefore, the electronic devices currently on the market cannot have both display function with high-resolution and sensing function with high-definition.

Therefore, there is a need to provide an improved electronic device to alleviate and/or obviate the above problems.

### SUMMARY

The present disclosure provides an electronic device, which includes: a substrate; a first conductive layer, an electronic unit, a sensor unit and a sensor unit driving circuit. The first conductive layer disposed on the substrate and provided with a first gate and a line segment connected to the first gate. The electronic unit and the sensor unit are respectively disposed on the substrate. The sensor unit driving circuit is disposed on the substrate and electrically connected to the electronic unit and the sensor unit. The sensor unit driving circuit includes a first transistor having the first gate, and a shape of the first gate is different from a shape of the line segment.

Other novel features of the disclosure will become more apparent from the following detailed description when taken in conjunction with the accompanying drawings.

### BRIEF DESCRIPTION OF DRAWINGS

FIG. 1 is a schematic diagram of the electronic device according to an embodiment of the present disclosure;

FIG. 2 is a schematic diagram of a corner area of the electronic device according to an embodiment of the present disclosure;

FIG. 3 is a schematic diagram of a basic driving circuit of the electronic device according to an embodiment of the present disclosure;

FIG. 4 is a detailed circuit diagram of the electronic device according to an embodiment of the present disclosure;

FIG. 5 is a signal timing diagram corresponding to the circuit structure of FIG. 4;

FIG. 6 is a schematic diagram of the layout of the electronic device according to an embodiment of the present disclosure;

FIG. 7 is a schematic diagram of a detailed circuit structure of the electronic device according to another embodiment of the present disclosure;

FIG. 8 is a signal timing diagram corresponding to the circuit structure of FIG. 7;

FIG. 9 is a schematic diagram of the layout of a reset transistor of the electronic device according to an embodiment of the present disclosure;

FIG. 10 is a schematic diagram of the layout of the reset transistor of the electronic device according to another embodiment of the present disclosure;

FIG. 11 is a schematic diagram of the layout of the reset transistor of the electronic device according to another embodiment of the present disclosure;

FIG. 12 is a schematic diagram of the layout of the reset transistor of the electronic device according to another embodiment of the present disclosure;

FIG. 13 is a cross-sectional view of the reset transistor according to an embodiment of the present disclosure;

FIG. 14 is a cross-sectional view of the reset transistor according to another embodiment of the present disclosure;

FIG. 15 is a cross-sectional view of the reset transistor according to another embodiment of the present disclosure;

FIG. 16 is a schematic diagram of the circuit structure of the electronic device according to another embodiment of the present disclosure; and

FIG. 17 is a schematic diagram of the circuit structure of the electronic device according to another embodiment of the present disclosure.

### DETAILED DESCRIPTION OF EMBODIMENT

Reference will now be made in detail to exemplary embodiments of the present application, examples of which are illustrated in the accompanying drawings. Wherever possible, the same reference numerals are used in the drawings and description to refer to the same or like parts.

Throughout the specification and the appended claims, certain terms may be used to refer to specific components. Those skilled in the art will understand that electronic device manufacturers may refer to the same components by different names. The present application does not intend to distinguish between components that have the same function but have different names. In the following description and claims, words such as “containing” and “comprising” are open-ended words, and should be interpreted as meaning “including but not limited to”.

The terms, such as “about”, “substantially”, or “approximately” are generally interpreted as within 10% of a given value or range, or as within 5%, 3%, 2%, 1% or 0.5% of a given value or range.

In the specification and claims, unless otherwise specified, ordinal numbers, such as “first” and “second”, used herein are intended to distinguish components rather than disclose explicitly or implicitly that names of the components bear the wording of the ordinal numbers. The ordinal numbers do not imply what order a component and another component are in terms of space, time or steps of a manufacturing method. Thus, what is referred to as a “first component” in the specification may be referred to as a “second component” in the claims.

In the present disclosure, the terms “the given range is from the first numerical value to the second numerical value” and “the given range falls within the range from the first numerical value to the second numerical value” mean that the given range includes the first numerical value, the second value, and other values therebetween.

In addition, the control method disclosed in the present disclosure may be used on electronic devices or vehicles equipped with electronic devices, wherein the electronic devices may include vehicle devices, imaging devices, assembly devices, backlight devices, antenna devices, tiled devices, touch electronic devices (touch display), curved electronic devices (curved display) or non-rectangular electronic devices (free shape display), but not limited thereto. The electronic device may include, for example, liquid crystal, light emitting diode, fluorescence, phosphor, other suitable display media, or a combination thereof, but not limited thereto. The display device may be a non-self-luminous display device or a self-luminous display device. The antenna device may be a liquid crystal type antenna device or a non-liquid crystal type antenna device, and the sensing device may be a sensing device that senses capacitance, light, heat energy or ultrasonic waves, but not limited thereto. The tiled device may include, for example, a display tiled device or an antenna tiled device, but not limited thereto. It is noted that the electronic device may be any combination of the above, but not limited thereto. In addition, the electronic device may be a bendable or flexible electronic device. It is noted that the electronic device may be any combination of the above, but not limited thereto. In addition, the shape of the electronic device may be a rectangular shape, a circular shape, a polygonal shape, a shape with curved edges, or other suitable shapes. The electronic device may have peripheral systems such as a driving system, a control system, a light source system, a shelf system, etc. to support the display device, antenna device or tiled device.

It is noted that the following are exemplary embodiments of the present application, but the present disclosure is not limited thereto, while a feature of some embodiments can be applied to other embodiments through suitable modification, substitution, combination, or separation. In addition, the present disclosure can be combined with other known structures to form further embodiments.

Unless otherwise defined, all terms (including technical and scientific terms) used herein have the same meaning as commonly understood by those skilled in the art related to the present application. It can be understood that these terms, such as those defined in commonly used dictionaries, should be interpreted as having meaning consistent with the relevant technology and the background or context of the present disclosure, and should not be interpreted in an idealized or excessively formal way, unless there is a special definition in the embodiment of the present application.

In addition, the term “adjacent” in the specification and claims is used to describe mutual proximity, and does not necessarily mean mutual contact.

In addition, descriptions such as “when” or “while” in the present application represent aspects such as “now, before or after”, and are not limited to situations that occur at the same time. In the present application, similar descriptions such as “disposed on” refer to the corresponding positional relationship between the two components, and do not limit whether there is contact between the two components, unless otherwise specified. Furthermore, when the present disclosure provides multiple functions, if the word “or” is used between the functions, it means that the functions may exist independently, but it does not exclude that multiple functions may exist simultaneously.

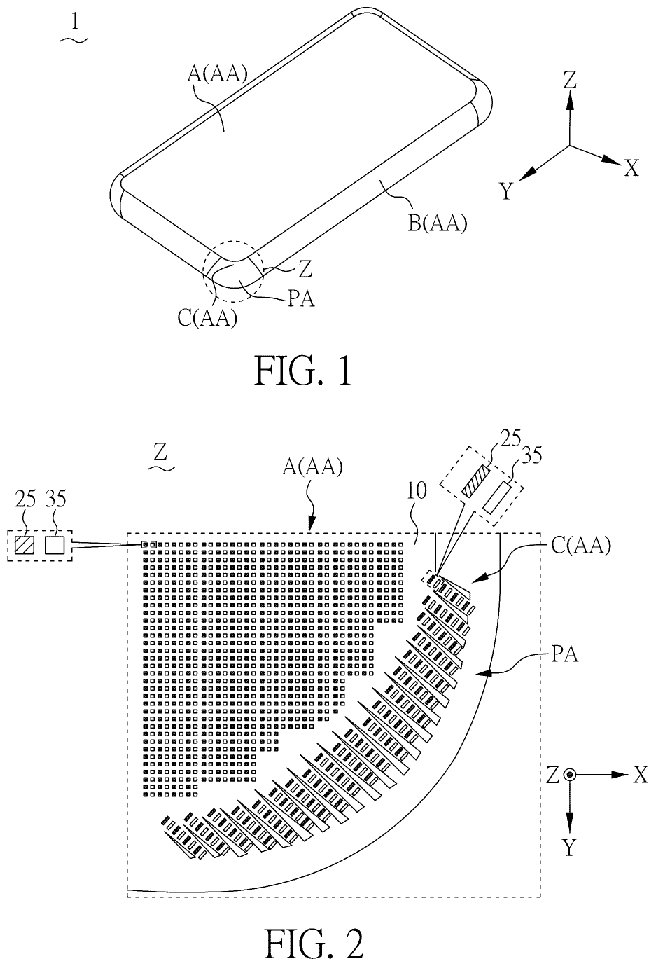

FIG. 1 is a schematic diagram of the electronic device 1 according to an embodiment of the present disclosure. As shown in FIG. 1, the electronic device 1 has an active area AA and an outer periphery area PA. The active area AA is a luminous area, which includes a main area A, multiple peripheral areas B, and multiple corner areas C, wherein the peripheral areas B may surround the main area A, for example. In one embodiment, the corner area C may be, for example, an arc-shaped structure, but it is not limited thereto.

FIG. 2 schematically illustrates an enlarged view of an outer area Z of the electronic device 1 according to an embodiment of the present disclosure, and please also refer to FIG. 1 at the same time. As shown in FIG. 2, the electronic device 1 may include a substrate 10, multiple electronic units 25 and multiple sensor units 35. The electronic units 25 and the sensor units 35 are respectively disposed on the substrate 10. In addition, in the outer area Z of the electronic device 1, the active area AA may include the main area A and the corner area C. The main area A and/or the corner area C may be provided with the electronic units 25 and/or the sensor units 35 as required. Similarly, the peripheral area B (not shown) may be provided with the sensor units 35 as required, or may not be provided with sensor units 35. The corner area C may be disposed between the main area A and the outer periphery area PA.

In one embodiment, the electronic unit 25 may be used to transmit electromagnetic waves, such as but not limited to light. In one embodiment, the electronic unit 25 is, for example, a light-emitting unit or a display unit. When the electronic unit 25 is a light-emitting unit, the electronic unit 25 may be, for example, an organic light-emitting diode (OLED), but it is not limited thereto. When the electronic unit 25 is a display unit, the electronic unit 25 may be, for example, a thin film transistor (TFT) or liquid crystal, but it is not limited thereto. For convenience of explanation, in the following description, the electronic unit 25 is exemplified by an organic light-emitting diode.

In one embodiment, the sensor unit 35 may be used to receive electromagnetic waves, such as but not limited to light. In one embodiment, the sensor unit 35 may be a light sensor unit, such as but not limited to an organic photodiode (OPD). The multiple sensor units 35 may be used to sense ambient light or fingerprints, for example, while it is not limited thereto.

In one embodiment, in the main area A and/or the corner area C, the electronic units 25 and the sensor units 35 may be arranged in a staggered manner, but may also be arbitrarily arranged according to needs. In one embodiment, the square measure of the main area A may be different from the square measure of the corner area C. In one embodiment, the shape of the main area A may be different from the shape of the corner area C. In one embodiment, the size of the electronic unit 25 and/or the sensor unit 35 in the main area A may be different from the size of the electronic unit 25 and/or the sensor unit 35 in the corner area C; for example, the electronic unit 25 in the main area A may be smaller than the size of the electronic unit 25 in the corner area C, and the size of the sensor unit 35 in the main area A may be smaller than the size of the sensor unit 35 in the corner area C, but it is not limited thereto.

Please refer to FIG. 1 and FIG. 2 at the same time. In one embodiment, the active area AA (including the main area A and the corner area C) of the electronic device 1 is provided with the electronic units 25 and the sensor units 35 at the same time, and the peripheral area B (for example, multiple sides) of the electronic device 1 is provided with the sensor units 35, so as to achieve the effect of sensing multiple fingerprints at the same time, thereby improving the accuracy of sensing.

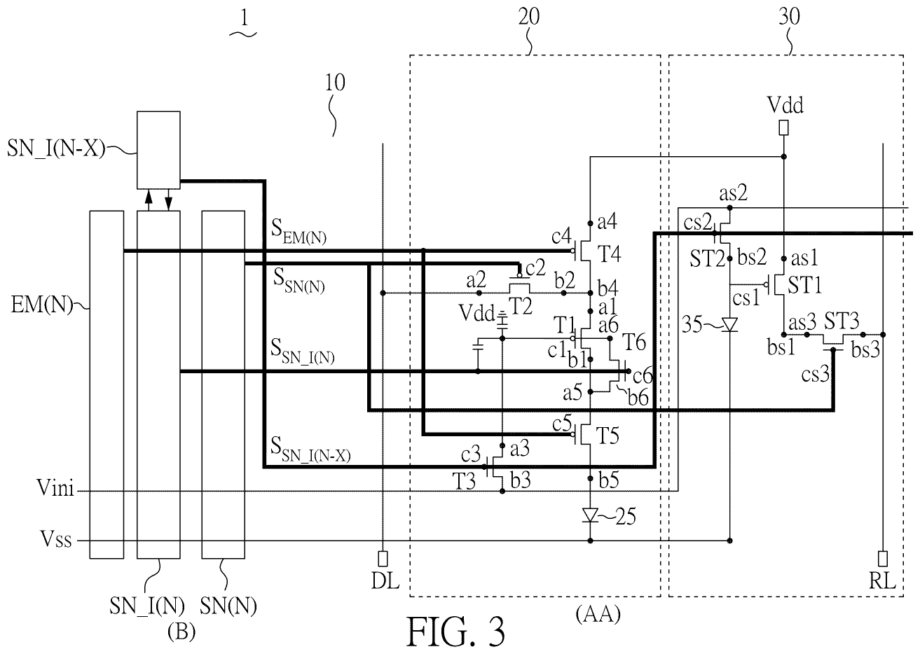

Next, the basic driving method of the electronic unit 25 and the sensor unit 35 will be described. FIG. 3 is a schematic diagram of the basic driving circuit of the electronic device 1 according to an embodiment of the present disclosure, and please refer to FIG. 1 and FIG. 2 at the same time, wherein FIG. 3 shows the basic driving circuit of one electronic unit 25 and one sensor unit 35, while those skilled in the art can deduce the implementation aspect of multiple electronic units 25 and multiple sensor units 35. In more detail, the electronic device 1 may have multiple groups of scan lines (not shown), each group of scan lines having at least one electronic unit, and the electronic unit 25 in FIG. 3 is, for example, the electronic unit in the N-th group of scan lines.

As shown in FIG. 3, in one embodiment, the electronic device 1 may include an electronic unit driving circuit 20 disposed on the substrate 10, and the electronic unit driving circuit 20 is electrically connected to the electronic unit 25. The electronic unit driving circuit 20 may be disposed, for example, in the active area AA. The electronic unit driving circuit 20 may include a driving transistor T1, a data writing transistor T2, a reset transistor T3, a transistor T4, a transistor T5 and a switch transistor T6, but it is not limited thereto, wherein at least one of the aforementioned transistors T1 to T6 may be electrically connected to the electronic unit 25. The driving transistor T1 may include a first end a1, a second end b1 and a control end c1, wherein the first end a1 may be a drain or a source, the second end b1 may be a drain or a source, and the control end c1 may be the gate. The data writing transistor T2 may include a first end a2, a second end b2 and a control end c2, wherein the first end a2 may be a drain or a source, the second end b2 may be a drain or a source, and the control end c2 may be a gate. The reset transistor T3 may include a first end a3, a second end b3 and a control end c3, wherein the first end a3 may be a drain or a source, the second end b3 may be a drain or a source, and the control end c3 may be a gate. The transistor T4 may include a first end a4, a second end b4, and a control end c4, wherein the first end a4 may be a drain or a source, the second end b4 may be a drain or a source, and the control end c4 may be a gate. The transistor T5 may include a first end a5, a second end b5, and a control end c5, wherein the first end a5 may be a drain or a source, the second end b5 may be a drain or a source, and the control end c5 may be a gate. The switch transistor T6 may include a first end a6, a second end b6, and a control end c6. The first end a6 may be a drain or a source, the second end b6 may be a drain or a source, and the control end c6 may be a gate.

In one embodiment, the material of the driving transistor T1, the data writing transistor T2, the transistor T4 and the transistor T5 may include polycrystalline silicon, such as low temperature poly-silicon (LTPS), and the material of the reset transistor T3 and the switch transistor T6 may include metal oxide, such as indium gallium zinc oxide (IGZO), but it is not limited thereto.

In addition, the electronic device 1 may include a sensor unit driving circuit 30, which is disposed on the substrate 10 and is electrically connected to the electronic unit 25 and the sensor unit 35. The sensor unit driving circuit 30 may be disposed in the active area AA, for example. The sensor unit driving circuit 30 may include a driving transistor ST1, a reset transistor ST2 and a data transmission transistor ST3, but it is not limited thereto. The driving transistor ST1 may include a first end as1, a second end bs1 and a control end cs1, wherein the first end as1 may be a drain or a source, the second end bs1 may be a drain or a source, and the control end cs1 may be a gate. The reset transistor ST2 may include a first end as2, a second end bs2 and a control end cs2, wherein the first end as2 may be a drain or a source, the second end bs2 may be a drain or a source, and the control end cs2 may be a gate. The data transmission transistor ST3 may include a first end as3, a second end bs3 and a control end cs3, wherein the first end as3 may be a drain or a source, the second end bs3 may be a drain or a source, and the control end cs3 may be a gate.

In one embodiment, the material of the driving transistor ST1 may include polycrystalline silicon, such as LTPS, the material of the reset transistor ST2 may include metal oxide, such as IGZO, and the material of the data transmission transistor ST3 may include polycrystalline silicon (such as LTPS) or metal oxide (such as IGZO), but it is not limited thereto.

In addition, in one embodiment, the electronic device 1 may also include multiple driving units SN(N), SN_I(N−X), SN_I(N) and EM(N) disposed on the substrate 10, wherein SN_I(N−X) and SN_I(N) are the same driving unit but drive different scan lines. The driving units SN(N), SN_I(N−X), SN_I(N), EM(N) may be disposed, for example, in an area of the outer area Z outside the active area AA, such as the outer periphery area PA, but it is not limited thereto. In one embodiment, the driving units SN(N), SN_I(N−X), SN_I(N) and EM(N) may be, for example, gate drivers of the aforementioned transistors T1 to T6 or ST1 to ST3, but it is not limited thereto.

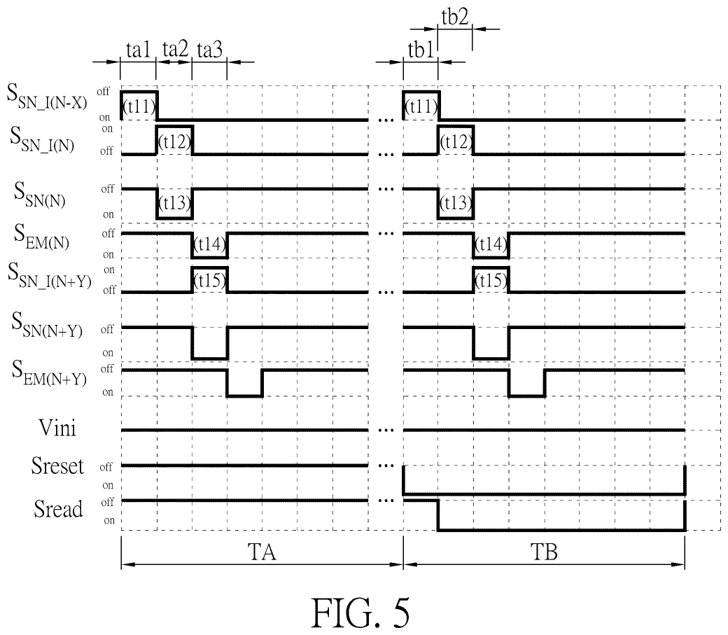

Furthermore, when the electronic unit driving circuit 20 and the sensor unit driving circuit 30 shown in FIG. 3 correspond to the N-th group of scan lines of the electronic device 1, in general, the driving unit SN(N) may be, for example, a gate driver that drives LTPS transistors in the N-th group of scan lines to write data, the driving unit EM(N) may be, for example, a gate driver that drives the LTPS transistors in the N-the group of scan lines to emit light, the driving unit SN_I(N) may be, for example, a gate driver that drives the IGZO transistors in the N-th group of scan lines to be turned on, the driving unit SN(N−X) (not shown) may be, for example, a gate driver that drives the LTPS transistors in the first X groups of scan lines (each group includes at least one scan line) to write data, the driving unit SN_I(N−X) may be, for example, a gate driver that drives the IGZO transistors in the first X groups of scan lines to be turned on, where X may be a positive integer greater than or equal to 1 (X≥1). For convenience of explanation, X is exemplified by 1 in the following description. It is noted that in the present disclosure, in order to integrate the electronic unit driving circuit 20 and the sensor unit driving circuit 30, the transistors of the electronic unit driving circuit 20 and the sensor unit driving circuit 30 in the N-th group of scan lines not only may be driven by the driving units SN(N), EM(N) and SN_I(N), but also may be driven by the driving units SN(N−X) and SN_I(N−X) corresponding to the first X groups of scan lines, or even may be driven by the driving units (for example, SN(N+Y), SN_I(N+Y) as shown in FIGS. 5, 7 and 8) corresponding to the last Y groups of scan lines (each group includes at least one scan line), where Y may be a positive integer greater than or equal to 0 (Y≥0).

In addition, in one embodiment, the driving units SN(N), SN_I(N−X), SN_I(N) and EM(N) may each include a transistor, or the driving units SN(N), SN_I(N−X), SN_I(N) and EM(N) may each be regarded as a transistor.

Next, the details of the electronic unit driving circuit 20 will be described.

In one embodiment, the first end a1 of the driving transistor T1 may be electrically connected to the second end b2 of the data writing transistor T2 and the second end b4 of the transistor T4. The second end a1 of the driving transistor T1 may be electrically connected to the first end a5 of the transistor T5, and the control end c1 of the driving transistor T1 may be electrically connected to the first end a6 of the switch transistor T6. The first end a2 of the data writing transistor T2 may be electrically connected to a data line DL, and the control end c2 of the data writing transistor T2 may be electrically connected to the driving unit SN(N). The first end a3 of the reset transistor T3 may be electrically connected to the control end c1 of the driving transistor T1, and forms a capacitor with a high voltage Vdd. The second end b3 of the reset transistor T3 may be electrically connected to an initial signal Vini, and the control end c3 of the reset transistor T3 may be electrically connected to the driving unit SN_I(N−X). The first end a4 of the transistor T4 may be electrically connected to the high voltage Vdd, and the control end c4 of the transistor T4 may be electrically connected to the driving unit EM(N). The second end b5 of the transistor T5 may be electrically connected to the electronic unit 25, and the control end c5 of the transistor T5 may be electrically connected to the driving unit EM(N). The second end b6 of the switch transistor T6 may be electrically connected to the first end a5 of the transistor T5, and the control end c6 of the switch transistor T6 may be electrically connected to the driving unit SN_I(N). In one embodiment, the high voltage Vdd may be used to adjust the brightness of the electronic unit 25. One end of the electronic unit 25 is electrically connected to the second end b5 of the transistor T5, and the other end of the electronic unit 25 is electrically connected to a low voltage Vss.

Next, the details of the sensor unit driving circuit 30 will be described.

In one embodiment, the first end as1 of the driving transistor ST1 is electrically connected to the high voltage Vdd, the second end bs1 of the driving transistor ST1 is electrically connected to the first end as3 of the data transmission transistor ST3, and the control end ac1 of the driving transistor ST1 may be electrically connected to the second end bs2 of the reset transistor ST2. The first end as2 of the reset transistor ST2 may be electrically connected to the initial signal Vini, and the control end cs2 of the reset transistor ST2 may be electrically connected to the driving unit SN_I(N−X). The second end bs3 of the data transmission transistor ST3 may be electrically connected to a signal readout line RL. In addition, when the material of the data transmission transistor ST3 includes metal oxide, the control end cs3 of the data transmission transistor ST3 may be electrically connected to the driving unit SN_I(N) and, when the material of the data transmission transistor ST3 includes polysilicon, the control end cs3 of the data transmission transistor ST3 may be electrically connected to the driving unit SN(N). It is noted that FIG. 3 shows a state in which the material of the data transmission transistor ST3 includes polysilicon, and thus the control end cs3 of the data transmission transistor ST3 may be electrically connected to the driving unit SN(N).

It can be seen that the driving unit SN_I(N−X) may be used to control the reset transistor T3 and the reset transistor ST2, in which “control” refers to controlling the transistor to be turned on or off. In other words, the driving unit SN_I(N−X)) may control a signal S_{SN_I(N-X)} to be transmitted to the reset transistor T3 and the reset transistor ST2, wherein the signal S_{SN_I(N-X)} may be regarded as a reset signal, for example. The driving unit SN_I(N) may be used to control the switch transistor T6 and the data transmission transistor ST3 (when its material includes IGZO). In other words, the driving unit SN_I(N) may control a signal S_{SN_I(N)} to be transmitted to the switch transistor T6 and the data transmission transistor ST3 (IGZO). The driving unit SN(N) may be used to control the data writing transistor T2 and the data transmission transistor ST3 (when its material includes LTPS). In other words, the driving unit SN(N) may control a signal S_{SN(N)} to be transmitted to the data writing transistor T2 and data transmission transistor ST3 (LTPS). The driving unit EM(N) may be used to control the transistor T4 and the transistor T5. In other words, the driving unit EM(N) may control a signal S_{EM(N)} to be transmitted to the transistor T4 and the transistor T5, wherein the signal S_{EM(N)} may be regarded as a switch signal, for example.

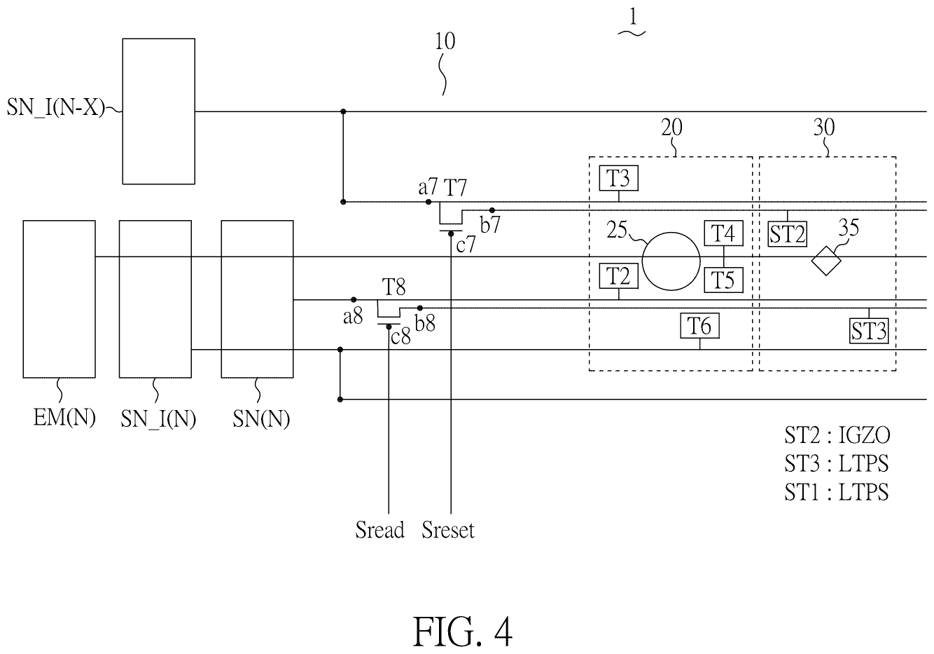

FIG. 4 is a detailed circuit diagram of the electronic device according to an embodiment of the present disclosure, and please refer to FIG. 1 to FIG. 3 at the same time. Since the circuit structures of the electronic unit driving circuit 20 and the sensor unit driving circuit 30 have been shown in FIG. 3, the circuit structures of the electronic unit driving circuit 20 and the sensor unit driving circuit 30 are simplified in FIG. 4 to make the illustration clear. Moreover, in FIG. 4, it takes the material of the data transmission transistor ST3 including polysilicon as an example, and thus the driving unit SN(N) may control the data transmission transistor ST3 to be turned on or off.

As shown in FIG. 4, the electronic device 1 may include a driving unit SN(N), a driving unit SN_I(N), a driving unit SN_I(N−1) and a driving unit EM(N). The driving unit SN_I(N−1) may be used to control the reset transistor T3 of the electronic unit driving circuit 20 and the reset transistor ST2 of the sensor unit driving circuit 30. The driving unit SN(N) may be used to control the data writing transistor T2 of the electronic unit driving circuit 20 and the data transmission transistor ST3 of the sensor unit driving circuit 30.

Although the reset transistor T3 and the reset transistor ST2 may share the driving unit SN_I(N−X), the reset transistor T3 and the reset transistor ST2 may need to be turned on at different times. Therefore, in one embodiment, the electronic device 1 may also include a transistor T7 disposed on the substrate 10. The transistor T7 may be electrically connected between the reset transistor ST2 and the reset transistor ST3. For example, a first end a7 of the transistor T7 may be electrically connected to the driving unit SN_I(N−X) and the reset transistor T3, and a second end b7 of the transistor T7 may be electrically connected to the reset transistor ST2. In addition, a control end c7 of the transistor T7 may be electrically connected to a reset control signal Sreset, so that the voltage level of the reset control signal Sreset may be used to control the transistor T7 to be turned on or off. It can be seen from this that, when the transistor T7 is turned off, the signal S_{SN_I(N-X)} provided by the driving unit SN_I(N−X) may be transmitted to the electronic unit driving circuit 20 but not to the sensor unit driving circuit 30 and, when the transistor T7 is turned on, the signal S_{SN_I(N-X)} provided by the driving unit SN_I(N−X) may be transmitted to the sensor unit driving circuit 30 through the transistor T7. As a result, the switching time of the reset transistor T3 and the reset transistor ST2 may be controlled.

In one embodiment, although the data transmission transistor ST3 and the data writing transistor T2 may share the driving unit SN(N), the data writing transistor T2 and the data transmission transistor ST3 may need to be turned on at different times, so that the electronic device 1 may further include a transistor T8, wherein a first end a8 of the transistor T8 may be electrically connected to the driving unit SN(N) and the data writing transistor T2, a second end b8 of the transistor T8 may be electrically connected to the data transmission transistor ST3, and a control end c8 of the transistor T8 may be electrically connected to a readout control signal Sread, where the voltage level of the readout control signal Sread may be used to control the transistor T8 to be turned on or off. It can be seen from this that, when the transistor T8 is turned off, the signal S_{SN(N)} provided by the driving unit SN(N) may be transmitted to the electronic unit driving circuit 20 but not to the sensor unit driving circuit 30 and, when the transistor T8 is turned on, the signal S_{SN(N)} provided by the driving unit SN(N) may be transmitted to the sensor unit driving circuit 30, so that the switching time of the data writing transistor T2 and the data transmission transistor ST3 may be controlled.

It is noted that, in another embodiment, when the data transmission transistor ST3 is an IGZO transistor, the switch transistor T6 (shown in FIG. 3) and the data transmission transistor ST3 may share the driving unit SN_I(N). In this case, the first end a8 of the transistor T8 may, for example, change to be electrically connected to the driving unit SN_I(N) and the switch transistor T6, while it is not limited thereto.

FIG. 5 is a signal timing diagram corresponding to the circuit structure of FIG. 4, and please refer to FIG. 3 at the same time.

In one embodiment, the electronic device 1 may execute a display mode and a sensing mode, wherein the time for executing the display mode once is defined as a display frame TA, and the time for executing the sensing mode once is defined as a sensing frame TB. In one embodiment, the display mode may include a reset phase, a data writing phase, and a light-emitting phase, and the sensing mode may include a reset phase and a data transmission phase.

As shown in FIG. 5, the display frame TA may include multiple sub-periods, such as ta1˜ta3, and the sensing frame TB may include multiple sub-periods, such as tb1˜tb2. In addition, in the example of FIG. 5, the sensing mode is executed later than the display mode. For example, the first sensing frame TB may follow the first display frame TA and at least partially overlap with the second display frame TA.

In addition, in the example of FIG. 5, the signals S_{SN_I(N-X)} and S_{SN_I(N)} are set to turn on the transistor at a high voltage, and the signal S_{SN(N)}, the signal S_{EM(N)}, the reset control signal Sreset and the readout control signal Sread are set to turn on the transistor at a low voltage, but it is not limited thereto in actual application.

First, the operation process of the display mode is explained by taking the first display frame TA as an example.

In the first sub-period ta1 of the display frame TA, the signal S_{SN_I(N-X)} provided by the driving unit SN_I(N−X) changes from low voltage to high voltage (it may be regarded as the transistor of the driving unit SN_I(N−X) being turned on, and thus the first sub-period ta1 of the display frame TA may be a turn-on period t11 of the transistor of the driving unit SN_I(N−X), so that the reset transistor T3 of the electronic unit driving circuit 20 is turned on to receive the initial signal Vini and, at this moment, the remaining transistors are turned off, thereby executing the reset phase of the display mode. It is noted that, since the reset control signal Sreset is at a high voltage level at this moment and the transistor T7 is turned off, the control end cs2 of the reset transistor ST2 does not receive the signal S_{SN_I(N-X)}, so that the reset transistor ST2 is turned off.

In the second sub-period ta2 of the display frame TA, the signal S_{SN_I(N)} provided by the driving unit SN_I(N) changes from low voltage to high voltage (it may be regarded as the transistor of the driving unit SN_I(N) being turned on, and thus the second sub-period ta2 of the display frame TA may be a turn-on period t12 of the transistor of the driving unit SN_I(N)), so that the switch transistor T6 of the electronic unit driving circuit 20 is turned on. At the same time, the signal S_{SN(N)} provided by the driving unit SN(N) changes from high voltage to low voltage (it may also be regarded as the transistor of the driving unit SN(N) being turned on, and thus the second sub-period ta2 of the display frame TA may be a turn-on period t13 of the transistor of the driving unit SN(N)), so that the data writing transistor T2 of the electronic unit driving circuit 20 is turned on to receive the data signal Data and, at this moment, the other transistors are turned off, thereby executing the data writing phase of the display mode. It is noted that, since the readout control signal Sread is at a high voltage at this moment, the transistor T8 is turned off, and thus the control end cs3 of the data transmission transistor ST3 does not receive the signal S_{SN(N)}, so that the data transmission transistor ST3 is also turned off.

In the third sub-period ta3 of the display frame TA, the signal S_{EM(N)} provided by the driving unit EM(N) changes from high voltage to low voltage (it may be regarded as the transistor of the driving unit EM(N) being turned on, and thus the third sub-period ta3 of the display frame TA may be a turn-on period t14 of the transistor of the driving unit EM(N)), so that the transistor T4 and the transistor T5 of the electronic unit driving circuit 20 are turned on. At the same time, the driving transistor T1 is turned on under the influence of the transistor T4 and the transistor T5 and, at this moment, the other transistors are turned off, so that the light-emitting phase of the display mode may be executed.

Next, the operation process of the sensing mode is explained.

In the first sub-period tb1 of the sensing frame TB, the signal S_{SN_I(N-X)} provided by the driving unit SN_I(N−X) changes from low voltage to high voltage (it may be regarded as the transistor of the driving unit SN_I(N−X) being turned on, and thus the first sub-period tb1 of the sensing frame TB may be a turn-on period t11 of the transistor of the driving unit SN_I(N−X)). At the same time, the reset control signal Sreset changes from high voltage to low voltage, so that the transistor T7 is turned on and, at this moment, the control end cs2 of the reset transistor ST2 may receive the driving unit signal S_{SN_I(N-X)}, and thus the reset transistor ST2 may be turned on and receive the initial signal Vini. Therefore, the reset phase of the sensing mode may be executed. Furthermore, the sensor unit 35 may sense a signal, and the driving transistor ST1 may be turned on under the influence of the reset transistor ST2, thereby amplifying the signal sensed by the sensor unit 35.

In the second sub-period tb2 of the sensing frame TB, the signal S_{SN(N)} provided by the driving unit SN(N) changes from high voltage to low voltage (it may be regarded as the transistor of the driving unit SN(N) being turned on, and thus the second sub-period tb2 of the sensing frame TB may be a turn-on period t13 of the transistor of the driving unit SN(N)). At the same time, the readout control signal Sread changes from high voltage to low voltage, and the transistor T8 is turned on, so that the control end cs3 of the data transmission transistor ST3 may receive the signal S_{SN_I(N-X)} for being turned on, thereby transmitting the signal sensed by the sensor unit 35 to the signal readout line RL. Therefore, the data transmission phase of the sensing mode can be executed.

In addition, although in the example of FIG. 5, the transistors T7 and T8 are turned on in different sub-periods of the sensing frame TB, in another embodiment, the transistors T7 and T8 may also be turned on at the same time point, for example, both may be turned on in the first sub-period tb1 of the sensing frame TB. For example, the reset control signal Sreset and the readout control signal Sread both change from high voltage to low voltage

In addition, in the example of FIG. 5, although the sensing mode is executed later than the display mode, in another embodiment, the sensing mode and the display mode may also be executed at the same time, that is, the display frame TA and the sensing frame TB may also be synchronized. In this case, during the first display sub-period ta1, the reset control signal Sreset may change from a high voltage to a low voltage. At this moment, the transistor T7 is turned on, and then the reset transistor T3 and the reset transistor ST2 may be turned on at the same time. In the second display sub-period ta2, the readout control signal Sread may change from high voltage to low voltage. At this moment, the transistor T8 is turned on, and the data writing transistor T2 may receive the data signal Data, so that the data transmission transistor ST3, the driving transistor ST1, the switch transistor T6 and the data writing transistor T2 may be turned on at the same time, while it is not limited thereto.

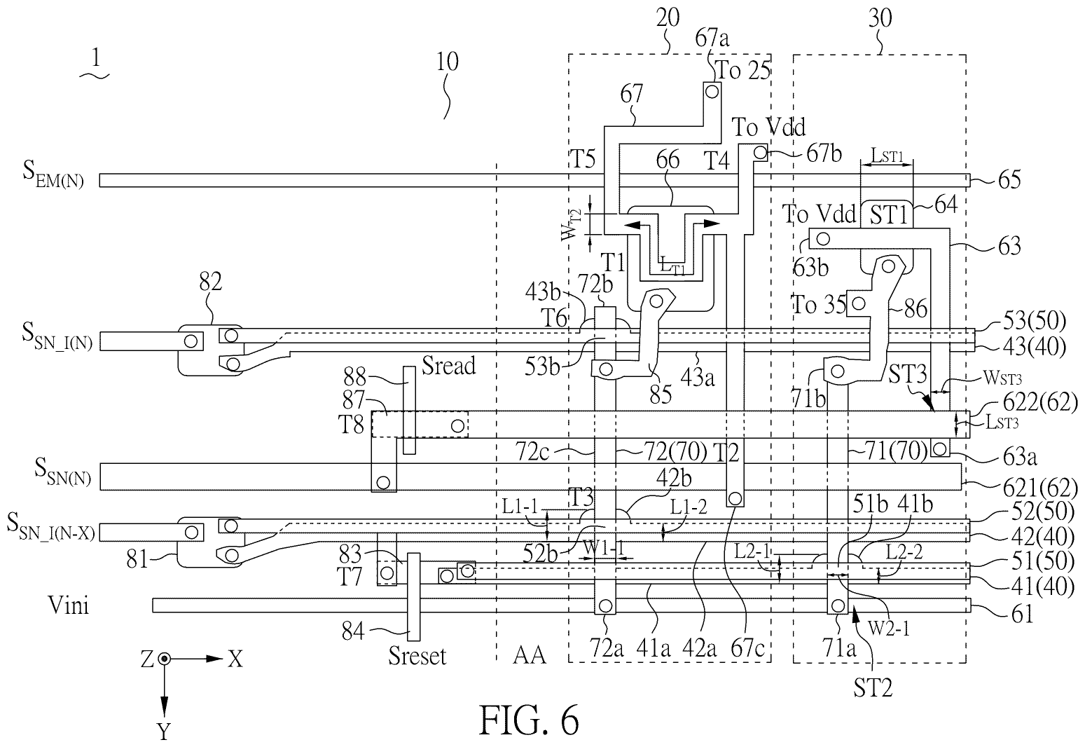

Next, the layout of the electronic device 1 will be described. FIG. 6 is a schematic diagram of the layout of the electronic device 1 according to an embodiment of the present disclosure, which may correspond to the circuit structures of FIG. 3 and FIG. 4, wherein FIG. 6 shows the layout in a top view. It is noted that FIG. 6 is an example in which the material of the data transmission transistor ST3 includes polysilicon. Therefore, the control end cs3 of the data transmission transistor ST3 may be electrically connected to the driving unit SN(N).

### [Layout of the Reset Transistor ST2 and the ‘Transistor T7]

As shown in FIG. 6, the electronic device 1 includes a first conductive layer 40 disposed on the substrate 10. The first conductive layer 40 may include a sub-conductive layer 41. The sub-conductive layer 41 includes a line segment 41a and a gate 41b. The line segment 41a is connected to the gate 41b, wherein the gate 41b may be, for example, an area overlapping a semiconductor layer 70. The reset transistor ST2 of the sensor unit driving circuit 30 may have a gate 41b. In one embodiment, the electronic device 1 includes a second conductive layer 50 disposed on the substrate 10, and the second conductive layer 50 is disposed on the first conductive layer 40 in the Z direction. The second conductive layer 50 may include a sub-conductive layer 51, and the sub-conductive layer 51 is disposed on the sub-conductive layer 41 in the Z direction. The sub-conductive layer 51 may include a gate 51b, wherein the gate 51b may be, for example, an area overlapping the semiconductor layer 70. The reset transistor ST2 has a gate 51b. The gate 41b of the sub-conductive layer 41 and the gate 51b of the sub-conductive layer 51 may at least partially overlap in the Z direction. In one embodiment, the sub-conductive layer 41 and the sub-conductive layer 51 may receive the signal S_{SN_I(N-X)} from the driving unit SN_I(N−X) through a first metal layer 81. In one embodiment, the gate 41b of the sub-conductive layer 41 may be, for example, a bottom gate, the gate 51b of the sub-conductive layer 51 may be, for example, a top gate, and the gate 41b and the gate 51b may form the gate of the reset transistor ST2 (that is, the control end cs2 in FIG. 3).

In the top view direction (for example, −Z direction in FIG. 6), the shape of the gate 41b of the sub-conductive layer 41 is different from the shape of the line segment 41a. In the present disclosure, “different shapes” indicates, for example, that there is no proportional scaling relationship between the two shapes. On the contrary, if the relationship between the two shapes is proportionally scaled, it is “the same shape”. In one embodiment, the gate 41b having a width L2-1 and the shape of the gate 41b being different from the shape of the line segment 41a indicate that the width L2-1 of the gate 41b is different from the width Lline of the line segment 41a. In one embodiment, the width L2-1 of the gate 41b may be greater than the width Lline of the line segment 41a (L2-1>Lline), thereby reducing the leakage current of the reset transistor ST2. In one embodiment, the ratio of the width Lline of the line segment 41a to the width L2-1 of the gate 41b may satisfy the equation: (0.3 times the width L2-1 of the gate 41b)<the ratio<(0.7 times the width L2-1 of the gate 41b) (that is, 0.3×L2-1<Lline/L2-1<0.7×L2-1), but it is not limited thereto. In addition, in one embodiment, the shape of the gate 41b is different from the shape of the gate 51b. For example, the gate 51b may have a width L2-2, and the width L2-1 of the gate 41b is different from the width L2-2 of the gate 51b. In one embodiment, the width L2-1 of the gate 41b is greater than the width L2-2 of the gate 51b (L2-1>L2-2), while it is not limited thereto.

In one embodiment, the electronic device 1 further includes a semiconductor layer 70 disposed on the substrate 10. The material of the semiconductor layer 70 may include metal oxide (for example, IGZO) and/or polycrystalline silicon (for example, LTPS), but it is not limited thereto. The reset transistor ST2 may include a first semiconductor 71, wherein the first semiconductor 71 may be, for example, at least a portion of the semiconductor layer 70, but it is not limited thereto. One end 71a of the first semiconductor 71 may be electrically connected to the initial signal Vini through a third conductive layer 61, and the other end 71b of the first semiconductor 71 may be electrically connected to the driving transistor ST1 through a sixth metal layer 86.

Accordingly, the gate 41b of the sub-conductive layer 41 and the gate 51b of the sub-conductive layer 51 may be used as the control end cs2 of the reset transistor ST2, and the first semiconductor 71 may at least partially overlap the gates 41b and 51b for use as a channel of the reset transistor ST2. Furthermore, one end 71a of the first semiconductor 71 may be used as the first end as2 of the reset transistor ST2, and the other end 71b of the first semiconductor 71 may be used as the second end bs2 of the reset transistor ST2, while it is not limited thereto. In addition, since the first semiconductor 71 may overlap the gate 41b, the channel length of the reset transistor ST2 may be regarded as equal to the width L2-1 of the gate 41b. The channel width of the reset transistor ST2 may be equal to the width W2-1 of the first semiconductor 71.

In one embodiment, the sub-conductive layer 41 and the sub-conductive layer 51 may be electrically connected to the transistor T7. In one embodiment, the transistor T7 may be formed of a third metal layer 83 and a fourth metal layer 84, wherein the third metal layer 83 may include, for example, an LTPS semiconductor, and the fourth metal layer 84 may be a conductive layer, which may be used as the gate of transistor T7 (that is, control end c7). As a result, by turning on or off the transistor T7, it is able to control whether the signal S_{SN_I(N-X)} provided by the driving unit SN_I(N−X) enters the sub-conductive layer 41 and the sub-conductive layer 51. In one embodiment, the third metal layer 83 can be electrically connected to the sub-conductive layer 41 and the sub-conductive layer 51 through bridging. In one embodiment, the third metal layer 83 may be electrically connected to the sub-conductive layer 42 and the sub-conductive layer 52 through bridging.

Accordingly, the structure of the reset transistor ST2 can be understood.

### [Layout of Driving Transistor ST1, Data Transmission Transistor ST3 and Transistor T8]

In one embodiment, the electronic device 1 may further include a fourth conductive layer 62, wherein the fourth conductive layer 62 may include a sub-conductive layer 621 and a sub-conductive layer 622. The fourth conductive layer 62 may be used to receive the signal S_{SN(N)} transmitted by the driving unit SN(N). In addition, the electronic device 1 may further include a fifth conductive layer 63. The fifth conductive layer 63 may be disposed on a different layer from the fourth conductive layer 62 in the Z direction, but it is not limited thereto. One end 63a of the fifth conductive layer 63 may be electrically connected to the signal readout line RL, and the other end 63b of the fifth conductive layer 63 may be electrically connected to the high voltage Vdd. In one embodiment, the sub-conductive layer 622 of the fourth conductive layer 62 and the fifth conductive layer 63 may form the data transmission transistor ST3, wherein the sub-conductive layer 622 of the fourth conductive layer 62 may be used as the data transmission transistor ST3. In the control end cs3, one end 63a of the fifth conductive layer 63 may be used as the second end bs3 of the data transmission transistor ST3, and a portion of the fifth conductive layer 63 may be used as the first end as3 of the data transmission transistor ST3. In one embodiment, a portion of the fifth conductive layer 63 may be used as a channel for the driving transistor ST1. In one embodiment, another portion of the fifth conductive layer 63 may be used as a channel for the data transmission transistor ST3.

In one embodiment, the sub-conductive layer 622 of the fourth conductive layer 62 may be electrically connected to the transistor T8. In one embodiment, the transistor T8 may be formed of a seventh metal layer 87 and an eighth metal layer 88, wherein the seventh metal layer 87 may include, for example, an LTPS or IGZO semiconductor, and the eighth metal layer 88 may be a conductive layer, which may be used as the gate of transistor T8 (that is, control end c8). As a result, by turning on or off the transistor T8, it is able to control whether the signal S_{SN(N)} provided by the driving unit SN(N) enters the sub-conductive layer 622 of the fourth conductive layer 62.

In addition, in one embodiment, the electronic device 1 may further include a sixth conductive layer 64. In the Z direction, the fifth conductive layer 63 and the sixth conductive layer 64 may be disposed at different layers. The fifth conductive layer 63 may be electrically connected to the reset transistor ST2 through the sixth metal layer 86. The sixth conductive layer 64 and the fifth conductive layer 63 may form the driving transistor ST1, wherein the sixth conductive layer 64 may be used as the control end cs1 of the driving transistor ST1, and a portion of the fifth conductive layer 63 may be used as the driving transistor ST1. The second end bs1 of the fifth conductive layer 63 may be used as the first end as1 of the driving transistor ST1.

Accordingly, the structures of the driving transistor ST1 and the data transmission transistor ST3 can be understood.

### [Layout of Reset Transistor T3]

In one embodiment, the first conductive layer 40 may further include a sub-conductive layer 42. The sub-conductive layer 42 may include a line segment 42a and a gate 42b. The line segment 42a is connected to the gate 42b. The reset transistor T3 of the electronic unit driving circuit 20 has a gate 42b. The second conductive layer 50 may also include a sub-conductive layer 52, and the sub-conductive layer 52 is disposed on the sub-conductive layer 42 in the Z direction. The sub-conductive layer 52 may include a gate 52b. The reset transistor T3 has a gate 52b, and the gate 52b may be electrically connected to the electronic unit 25. In addition, in the Z direction, the gate 42b of the sub-conductive layer 42 and the gate 52b of the sub-conductive layer 52 may at least partially overlap. In one embodiment, the sub-conductive layer 42 and the sub-conductive layer 52 may receive the signal S_{SN_I(N-X)} from the driving unit SN_I(N−X) through a first metal layer 81. The sub-conductive layer 42 and the sub-conductive layer 52 may be electrically connected to the sub-conductive layer 41 and the sub-conductive layer 51 through the transistor T7. In one embodiment, the gate 42b may be, for example, a bottom gate, the gate 52b may be, for example, a top gate, and the gate 42b and the gate 52b may form the gate (that is, the control end c3) of the reset transistor T3. In addition, in one embodiment, the line segment 41a may also be connected to the gate 42b, but it is not limited thereto. In addition, in one embodiment, the electronic device 1 may further include another conductive layer (not shown) disposed on the substrate 10, another conductive layer may have a connection portion (not shown), and the gate 41b and the gate 52b may be electrically connected through the connection portion, but it is not limited thereto. Furthermore, in the Z direction, another conductive layer may be disposed below the gate 41b and the line segment 41a, but may also be disposed between the gate 41b (or line segment 41a) and the gate 52b.

The lengths of the line segments 41a and 42a may be the same. In the top view direction (for example, the −Z direction in FIG. 6), the shape of the gate 42b is different from the shape of the line segment 42a (or line segment 41a). For example, the gate 42b may have a width L1-1, the line segment 42a (or line segment 41a) may have a width Lline, and the width L2-2 of the gate 42b may be different from the width Line of the line segment 42a (or line segment 41a). In one embodiment, the width L1-1 of the gate 42b may be greater than the width Lline of the line segment 42a (L1-1>Lline), thereby reducing the leakage current of the reset transistor T3. In one embodiment, the ratio of the width Lline of the line segment 42a to the width L1-1 of the gate 42b may satisfy the equation: (0.3 times the width L1-1 of the gate 42b)<the ratio<(0.7 times the width L1-1 of the gate 42b) (that is, 0.3×L2-1<Line/L1-1<0.7×L2-1), but it is not limited thereto. In addition, in one embodiment, the line segment 42a may have the same width Lline as the line segment 41a, so that the width L1-1 of the gate 42b may also be greater than the width Lline of the line segments 41a and 41b. In addition, in one embodiment, in the top view direction (such as the −Z direction in FIG. 6), the shape of the gate 42b may also be different from the shape of the gate 52b. For example, the gate 52b may have a width L1-2, and the width L1-1 of the gate 42b is different from the width L1-2 of the gate 52b. In one embodiment, the width L1-1 of the gate 42b may be greater than the width L1-2 of the gate 52b (L1-1>L1-2). In addition, in the top view direction (for example, the −Z direction in FIG. 6), the shape of the gate 52b may also be different from the line segment 41a, 42a or 52a. In one embodiment, the width L1-1 of the gate 52b may be smaller than or equal to the width Lline of the line segment 41a, 42a or 52a (L1-1≤Lline), but it is not limited thereto.

In addition, in one embodiment, the reset transistor T3 may include a second semiconductor 72, wherein the second semiconductor 72 may be, for example, at least a portion of the semiconductor layer 70, but it is not limited thereto. One end 72a of the second semiconductor 72 may be electrically connected to the initial signal Vini through the third conductive layer 61, and an extended portion 72c of the second semiconductor 72 may be electrically connected to the driving transistor T1 through a fifth metal layer 85.

Accordingly, the gate 42b of the sub-conductive layer 42 and the gate 52b of the sub-conductive layer 52 may be used as the control end c3 of the reset transistor T3, the second semiconductor 72 may at least partially overlap the gates 42b and 52b for use as a channel of the reset transistor T3, one end 72a of the second semiconductor 72 may be used as the second end b3 of the reset transistor T3, and the extended portion 72c of the second semiconductor 72 may be used as the first end a3 of the reset transistor T3, while it is not limited thereto. In addition, since the second semiconductor 72 may overlap the gate 42b, the channel length of the reset transistor T3 may be regarded to be equal to the width L1-1 of the gate 42b. The channel width of the reset transistor T3 may be equal to the width W1-1 of the second semiconductor 72.

As a result, the structure of the reset transistor T3 can be understood.

### [Layout of Switch Transistor T6]

In one embodiment, the first conductive layer 40 may further include a sub-conductive layer 43. The sub-conductive layer 41, the sub-conductive layer 42 and the sub-conductive layer 43 may be separated from each other, but it is not limited thereto. The sub-conductive layer 43 may include a line segment 43a and a gate 43b, and the line segment 43a is connected to the gate 43b. The switch transistor T6 of the electronic unit driving circuit 20 has a gate 43b. The second conductive layer 50 may also include a sub-conductive layer 53, and the sub-conductive layer 53 is disposed on the sub-conductive layer 43 in the Z direction. The sub-conductive layer 53 may include a gate 53b. The switch transistor T6 has a gate 53b. In addition, in the Z direction, the gate 43b of the sub-conductive layer 43 and the gate 53b of the sub-conductive layer 53 may at least partially overlap. In one embodiment, the sub-conductive layer 43 and the sub-conductive layer 53 may receive the signal S_{SN_I(N)} from the driving unit SN_I(N) through a second metal layer 82. In one embodiment, the gate 43b may be, for example, a bottom gate, the gate 53b may be, for example, a top gate, and the gate 43b and the gate 53b may form the gate of the switch transistor T6 (that is, the control end c6 in FIG. 3).

In one embodiment, in the top view direction (for example, the −Z direction in FIG. 6), the relationship between the shape of the gate 43b and the shape of the line segment 43a of the sub-conductive layer 43 may be applicable to the description of the relationship between the shape of the gate 41b and the shape of the line segment 41a of the sub-conductive layer 41, and thus a detailed description is deemed unnecessary. The line segment 43a and the line segment 41a may have the same width Lline. In addition, in the top view direction (for example, −Z direction in FIG. 6), the shape of the gate 43 b and the shape of the gate 53 b may be different.

In one embodiment, the extended portion 72c of the second semiconductor 72 may be used as the first end a6 of the switch transistor T6, and the other end 72b of the second semiconductor 72 opposite to the end 72a may be used as the second end b6 of the switch transistor T6, wherein the other end 72b of the second semiconductor 72 may be electrically connected to the transistor T5 (not shown), and the gate 43b of the sub-conductive layer 43 and the gate 53b of the sub-conductive layer 53 may be used as the control end c6 of the switch transistor T6, while it is not limited thereto. Accordingly, the structure of the switch transistor T6 can be understood.

### [Layout of Other Transistors (T1, T2, T4 and T5) of the Electronic Unit Driving Circuit 20]

In one embodiment, the electronic device 1 may further include a seventh conductive layer 65, an eighth conductive layer 66, and a ninth conductive layer 67. The seventh conductive layer 65 may be used to receive the signal S_{EM(N)} transmitted by the driving unit EM(N). In the Z direction, the eighth conductive layer 66 and the ninth conductive layer 67 may be disposed on different layers. The ninth conductive layer 67 may have a first end 67a, a second end 67b and a third end 67c, wherein the first end 67a may be electrically connected to the electronic unit 25, the second end 67b may be electrically connected to the high voltage 67b, and the third end 67c may be electrically connected to the data line DL. The ninth conductive layer 67 may also have a middle portion 67d, and the middle portion 67 may at least partially overlap the eighth conductive layer 66.

In one embodiment, a portion of the ninth conductive layer 67 and the eighth conductive layer 66 may be used to form the driving transistor T1. In one embodiment, the ninth conductive layer 67 and the seventh conductive layer 61 may be used to form the transistor T4 and the transistor T5, wherein the second end 67b of the ninth conductive layer 67 may be used as the first end a4 of the transistor T4, and the first end 67a of the ninth conductive layer 67 may be used as the second end b5 of the transistor T5. In one embodiment, the sub-conductive layer 621 of the fourth conductive layer 62 and the ninth conductive layer 67 may be used to form the data writing transistor T2, wherein the third end 67c of the ninth conductive layer 67 may be used as the first end a2 of the data writing transistor T2.

In one embodiment, a portion of the ninth conductive layer 67 may be used as a channel of the driving transistor T1. In one embodiment, another portion of the ninth conductive layer 67 may be used as a channel of the transistor T4, and still another portion of the ninth conductive layer 67 may be used as a channel of the transistor T5.

Accordingly, the structures of the driving transistors T1, T2, T4 and T5 may be understood.

Next, the size relationship between various transistors will be described.

In one embodiment, the material of the driving transistor ST1 and the data transmission transistor ST3 may include LTPS, the material of the reset transistor ST2 may include IGZO, the driving transistor T1 may have a channel length LT1, and the driving transistor ST1 may have channel length LST1. In one embodiment, the driving transistor T1 and the driving transistor ST1 may be electrically connected to different high voltages Vdd. In one embodiment, when the driving transistor T1 and the driving transistor ST1 are electrically connected to the same high voltage Vdd, the channel length LT1 of the driving transistor T1 may be equal to the channel length LST1 of the driving transistor ST1 (LT1=LST1). In one embodiment, when the driving transistor T1 and the driving transistor ST1 are electrically connected to different high voltages Vdd, the channel length LT1 of the driving transistor T1 may be greater than the channel length LST1 of the driving transistor ST1 (LT1>LST1), thereby reducing the leakage current of the sensor unit driving circuit 30. In addition, in one embodiment, the channel length LST1 of the driving transistor ST1 may be greater than the channel length L2-1 of the reset transistor ST2 (LST1>L2-1), thereby reducing the leakage current of the sensor unit driving circuit 30.

In one embodiment, the material of the driving transistor ST1 and the data transmission transistor ST3 may include LTPS, the material of the reset transistor ST2 may include IGZO, and the data transmission transistor ST3 may have a channel length LST3 and a channel width WST3. In one embodiment, the channel length LST3 of the data transmission transistor ST3 may be greater than the channel length L2-1 of the reset transistor ST2 (LST3>L2-1). In one embodiment, the channel width WST3 of the data transmission transistor ST3 may be smaller than the channel width W2-1 of the reset transistor ST2 (WST3<W2-1). As a result, the leakage current of the sensor unit driving circuit 30 may be reduced.

In one embodiment, the material of the driving transistor ST1 may include LTPS, the material of the reset transistor ST2 and the data transmission transistor ST3 may include IGZO, and the data transmission transistor ST3 may have a channel length LST3 and a channel width WST3. In one embodiment, the channel length LST3 of the data transmission transistor ST3 may be greater than the channel length L2-1 of the reset transistor ST2 (LST3>L2-1). In one embodiment, the channel width WST3 of the data transmission transistor ST3 may be smaller than the channel width W2-1 of the reset transistor ST2 (WST3<W2-1). As a result, the leakage current of the sensor unit driving circuit 30 may be reduced.

Accordingly, the layout of the electronic device 1 can be understood.

In the present disclosure, when the material of the driving transistor ST1, the reset transistor ST2 and/or the data transmission transistor ST3 of the sensor unit driving circuit 30 changes, the circuit structure between the sensor unit driving circuit 30 and the driving unit will also change. In the following description, different circuit structures will be explained.

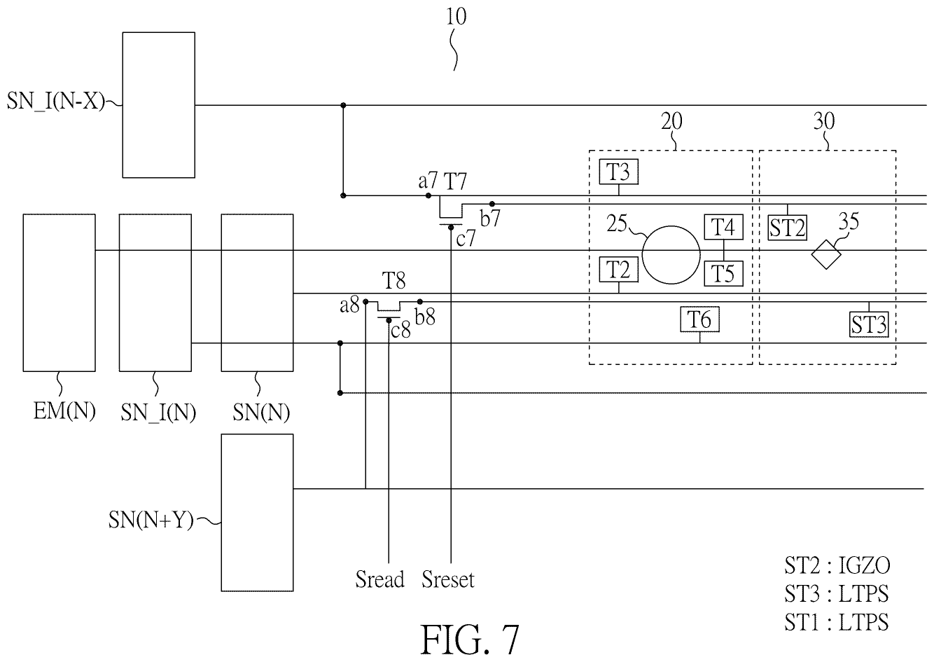

FIG. 7 is a schematic diagram of the detailed circuit structure of the electronic device 1 according to another embodiment of the present disclosure, and please refer to FIG. 1 to FIG. 6 at the same time. The features of the example in FIG. 7 may be applicable to the description of the example in FIG. 4, and thus the following description mainly focuses on the differences.

In the example of FIG. 7, the material of the driving transistor ST1 includes LTPS, the material of the reset transistor ST2 includes IGZO, the material of the data transmission transistor ST3 includes LTPS, and the portion of the electronic unit driving circuit 20 is the same as the example of FIG. 4. In addition, the reset transistor ST2 is driven by the driving unit SN_I(N−X).

The example of FIG. 7 is different from the example of FIG. 4 in that the electronic device 1 further includes a driving unit SN(N+Y) disposed in the peripheral area B, wherein Y may be equal to 1, for example. The driving unit SN(N+Y) may be electrically connected to the first end a8 of the transistor T8, and the second end b8 of the transistor T8 may be electrically connected to the data transmission transistor ST3. Therefore, the transistor T8 is driven by the driving unit SN(N+Y). For example, the driving unit SN(N+Y) may provide the signal S_{SN(N+Y)}. When the transistor T8 is turned on, the signal S_{SN(N+Y)} may enter the control end cs3 of the data transmission transistor ST3, thereby turning on the data transmission transistor ST3. In one embodiment, the driving unit SN(N+Y) may include a transistor, or may itself be a transistor. In other words, the driving unit SN(N+Y) may control the signal S_{SN(N+Y)} to be transmitted to the data transmission transistor ST3, wherein the signal S_{SN(N+Y)} may be regarded as a readout signal.

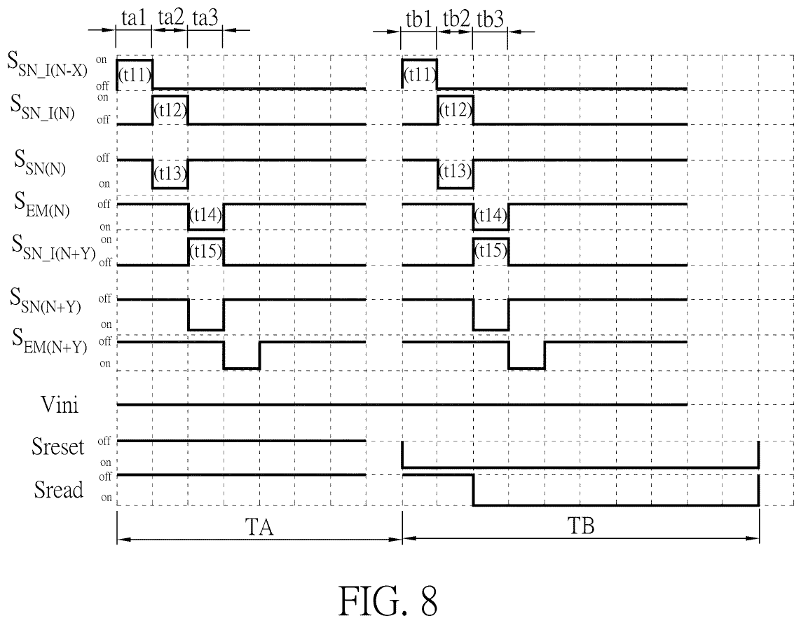

FIG. 8 is a signal timing diagram corresponding to the circuit structure of FIG. 7. In the example of FIG. 8, the operation process of the display mode is the same as that of the example of FIG. 5, and thus the following description mainly focuses on the sensing mode.

As shown in FIG. 8, in the first sub-period tb1 of the sensing frame TB, the signal S_{SN_I(N-X)} provided by the driving unit SN_I(N−X) changes from low voltage to high voltage and, at the same time, the reset control signal Sreset changes from high voltage to low voltage, so that the transistor T7 is turned on, and the control end cs2 of the reset transistor ST2 may receive the driving unit signal S_{SN_I(N-X)} for being turned on, so that the reset phase may be executed. Furthermore, the driving transistor ST1 may be turned on under the influence of the reset transistor ST2, thereby amplifying the signal sensed by the sensor unit 35. At this moment, the readout control signal Sread maintains a high voltage, so that the transistor T8 is turned off.

In the second sub-period tb2 of the sensing frame TB, the signal S_{SN_I(N-X)} provided by the driving unit SN_I(N−X) changes from a high voltage to a low voltage, causing the reset transistor ST2 to be turned off. At this moment, the signal S_{SN(N+Y)} provided by the driving unit SN(N+Y) maintains a low voltage, and the readout control signal Sread maintains a high voltage, so that the transistor T8 remains in a turn-off state. In the third sub-period tb3 of the sensing frame TB, the signal S_{SN(N+Y)} provided by the driving unit SN(N+Y) changes from a low voltage to a high voltage (it may be regarded as the transistor of the driving unit SN(N+Y) being turned on, and thus the third sub-period tb3 of the sensing frame TB may be a turn-on period t15 of the transistor of the driving unit SN(N+Y)). At the same time, the readout control signal Sread changes from high voltage to low voltage, and thus the transistor T8 is turned on, so that the control end cs3 of the data transmission transistor ST3 may receive the signal S_{SN(N+Y)} to be turned on, thereby executing the data transmission phase of the sensing mode. It is noted that at least one turn-on period t15 of the transistor of the driving unit SN(N+Y) and at least one turn-on period t14 of the transistor of the driving unit EM(N) may not overlap, but it is not limited thereto.

In one embodiment, the time length of a sensing frame TB may be greater than that of a display frame TA (TB>TA), but it is not limited thereto. In one embodiment, when the time length of a sensing frame TB is greater than that of a display frame TA (TB>TA), the sensing frame TB may at least partially overlap the next sensing frame TB, but it is not limited thereto.

In another embodiment, the time length of a display frame TA may also be greater than the time length of a sensing frame TB (TA>TB), wherein one display frame TA may at least partially overlap multiple sensing frames TB.

In another embodiment, the time length of one sensing frame TB may also be greater than the time length of one sensing frame TA (TB>TA), wherein one sensing frame TB may at least partially overlap multiple display frames TA.

Accordingly, the examples of FIG. 7 and FIG. 8 can be understood.

In addition to the example in FIG. 7, the circuit structure of the electronic device 1 of the present disclosure may also have different implementation aspects. Next, examples will be given with descriptions (please take the examples in FIG. 4 or FIG. 7 as a reference).

In one embodiment, the material of the driving transistor ST1 of the sensor unit driving circuit 30 may include LTPS, and the material of the reset transistor ST2 and the data transmission transistor ST3 may include IGZO. At this moment, the driving unit SN_I(N−X) may be electrically connected to the control end cs2 of the reset transistor ST2 through the transistor T7, and the driving unit SN_I(N) may be electrically connected to the control end cs3 of the data transmission transistor ST3 through the transistor T8, so that the reset transistor ST2 may be driven by the driving unit SN_I(N−X), and the data transmission transistor ST3 may be driven by the driving unit SN_I(N).

In one embodiment, the material of the driving transistor ST1 of the sensor unit driving circuit 30 may include LTPS, the material of the reset transistor ST2 and the data transmission transistor ST3 may include IGZO, and the electronic device 1 further includes a driving unit SN_I(N+Y). At this moment, the driving unit SN_I(N−X) may be electrically connected to the control end cs2 of the reset transistor ST2 through the transistor T7, and the driving unit SN_I(N+Y) may be electrically connected to the control end cs3 of the data transmission transistor ST3 through the transistor T8. Therefore, the reset transistor ST2 may be driven by the driving unit SN_I(N−X), and the data transmission transistor ST3 may be driven by the driving unit SN_I(N+Y).

In one embodiment, the materials of the driving transistor ST1, the reset transistor ST2 and the data transmission transistor ST3 of the sensor unit driving circuit 30 all include LTPS. Therefore, in this embodiment, the material of the reset transistor ST2 may be different from the material of the reset transistor T3. At this moment, the driving unit SN_I(N−X) may be electrically connected to the control end cs2 of the reset transistor ST2 through the transistor T7, and the driving unit SN(N) may be electrically connected to the control end cs3 of the data transmission transistor ST3 through the transistor T8. Therefore, the reset transistor ST2 may be driven by the driving unit SN(N), and the data transmission transistor ST3 may be driven by the driving unit SN_I(N).

In one embodiment, the material of the driving transistor ST1 and the data transmission transistor ST3 of the sensor unit driving circuit 30 may include LTPS, the material of the reset transistor ST2 may include IGZO, and the electronic device 1 may not have the transistors T7 and T8. In this case, the electronic device 1 may include at least two driving units SN_I(N−X), one of which is used to drive the reset transistor T3 in the electronic unit driving circuit 20, and the other is used to drive the reset transistor ST2 of the sensor unit driving circuit 30. In addition, the electronic device 1 may also include at least two driving units SN(N), one of which is used to drive the data writing transistor T2 of the electronic unit driving circuit 20, and the other is used to drive the data transmission transistor ST3 of the sensor unit driving circuit 30.

In one embodiment, the materials of the driving transistor ST1, the reset transistor ST2 and the data transmission transistor ST3 of the sensor unit driving circuit 30 may all include LTPS, and the electronic device 1 may not have the transistors T7 and T8. In this case, the electronic device 1 may include a driving unit SN(N−X) (not shown) for driving the reset transistor ST2 of the sensor unit driving circuit 30. In addition, the electronic device 1 may also include at least two driving units SN(N), one of which is used to drive the data writing transistor T2 of the electronic unit driving circuit 20, and the other is used to drive the data transmission transistor ST3 of the sensor unit driving circuit 30.

Accordingly, various implementation aspects of the circuit structure of the electronic device 1 can be understood. It is noted that the circuit structure of the present disclosure is not limited thereto.

In addition to the implementation aspect of FIG. 6, the layout of the reset transistors T2 and ST2 of the electronic device 1 of the present disclosure may also have other variations, which will be described in the following.

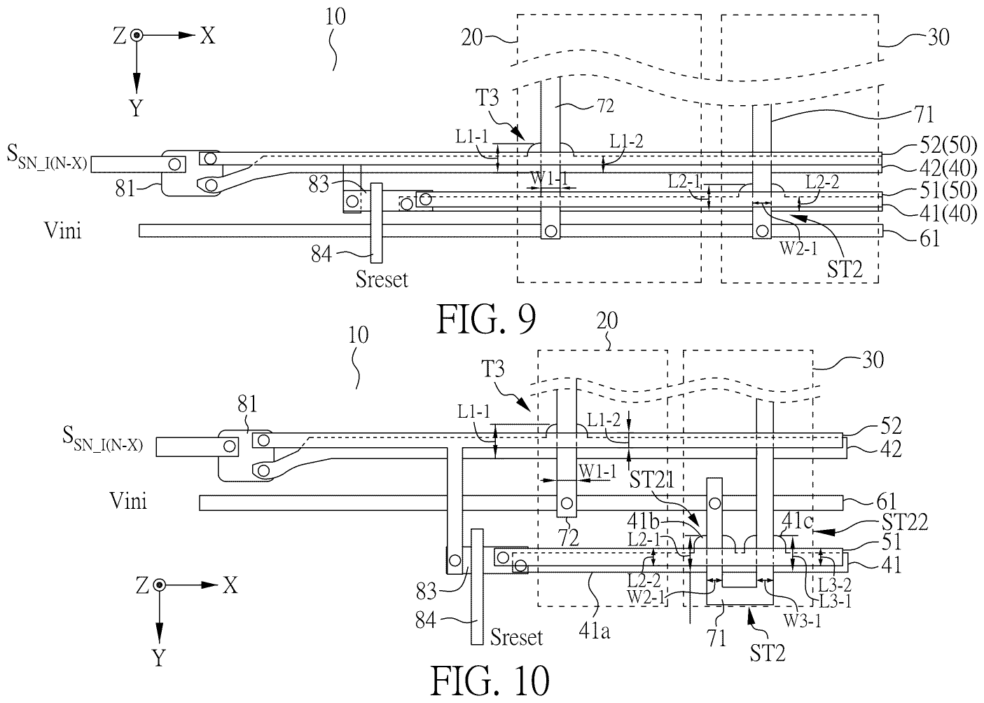

FIG. 9 is a schematic diagram of the layout of the reset transistors T3 and ST2 of the electronic device 1 according to an embodiment of the present disclosure, and please refer to FIG. 1 to FIG. 8 at the same time. In order to make the features clear, FIG. 9 only shows the layout of the reset transistors T3 and ST2, while the layout of the other transistors may refer to the exemplary content of FIG. 6.

As shown in FIG. 9, in one embodiment, the channel width W1-1 of the reset transistor T3 is different from the channel width W2-1 of the reset transistor ST2. In one embodiment, the channel width W1-1 of the reset transistor T3 may be greater than the channel width W2-1 of the reset transistor ST2 (W1-1>W2-1), while it is not limited thereto. In one embodiment, the channel length L1-1 of the reset transistor T3 is different from the channel length L2-1 of the reset transistor ST2. In one embodiment, the channel length L2-1 of the reset transistor ST2 may be greater than the channel length L1-1 of the reset transistor T3 (L2-1>L1-1), while it is not limited thereto. Through the above configuration, the sensor unit driving circuit 30 of the present disclosure may have lower leakage current, or may improve the accuracy of sensing.

FIG. 10 is a schematic diagram of the layout of the reset transistors T3 and ST2 of the electronic device 1 according to another embodiment of the present disclosure, and please refer to FIG. 1 to FIG. 9 at the same time. In order to make the features clear, FIG. 10 only shows the layout of the reset transistors T3 and ST2, while the layout of the other transistors may refer to the exemplary content of FIG. 6.

As shown in FIG. 10, the reset transistor ST2 may include multiple sub-transistors, such as a sub-transistor ST21 and a sub-transistor ST22, wherein the sub-transistor ST21 and the sub-transistor ST22 may be electrically connected, such as being connected in series. In one embodiment, the sub-conductive layer 41 may further include a gate 41c, wherein the sub-transistor ST21 may include gates 41b and 51, and the sub-transistor ST22 may include gates 41c and 51. In addition, a portion of the first semiconductor 71 may be used as a channel of the sub-transistor ST21, and another portion of the first semiconductor 71 may be used as a channel of the sub-transistor ST22.

In one embodiment, the sub-transistor ST21 may have a channel length L2-1 and a channel width W2-1, and the sub-transistor ST22 may have a channel length L3-1 and a channel width W3-1. In one embodiment, at least one of the channel length L2-1 of the sub-transistor ST21 and the channel length L3-1 of the sub-transistor ST22 may be greater than the channel length L1-1 of the reset transistor T3 (L2-1>L1-1, or L3-1>L1-1, or L2-1>L1-1, and L3-1>L1-1). In one embodiment, at least one of the channel width W2-1 of the sub-transistor ST21 and the channel width W3-1 of the sub-transistor ST22 may be smaller than the channel width W1-1 of the reset transistor T3 (W2-1<W1-1, or W3-1<W1-1, or W2-1<W1-1, and W3-1<W1-1). Through the above configuration, the sensor unit driving circuit 30 of the present disclosure may have lower leakage current.

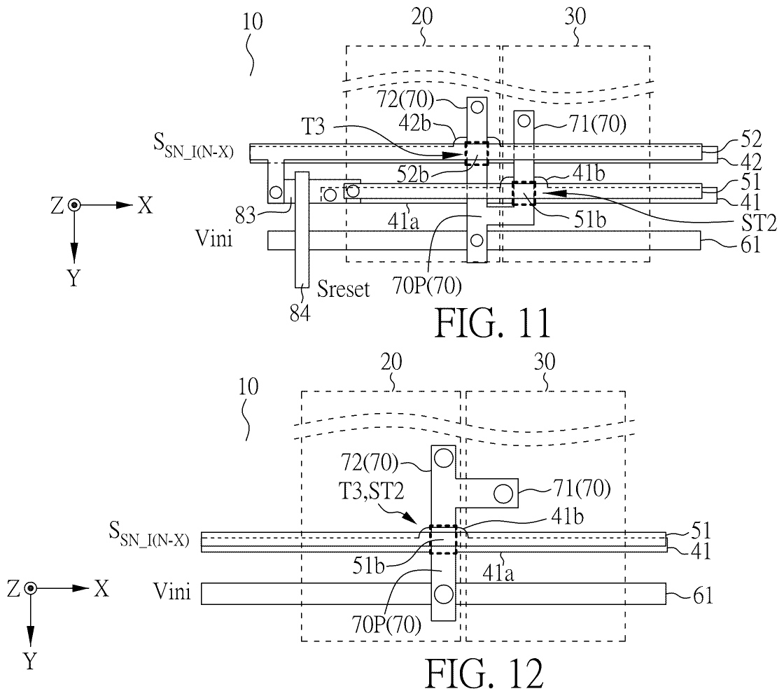

FIG. 11 is a schematic diagram of the layout of the reset transistors T3 and ST2 of the electronic device 1 according to another embodiment of the present disclosure, and please refer to FIG. 1 to FIG. 10 at the same time. In order to make the features clear, FIG. 11 only shows the layout of the reset transistors T3 and ST2, while the layout of the other transistors may refer to the exemplary content of FIG. 6.

As shown in FIG. 11, the semiconductor layer 70 may include a pattern portion 70p, and the first semiconductor 71 of the reset transistor ST2 and the second semiconductor 72 of the reset transistor T3 may share the pattern portion 70p. For example, when the first semiconductor 71 and the second semiconductor 72 are made of the same material, such as IGZO, the first semiconductor 71 and the second semiconductor 72 may be connected together. In one embodiment, the reset transistor ST2 and the reset transistor T3 may share the same end, such as the source, and the other ends (such as the drains) of the reset transistor ST2 and the reset transistor T3 are respectively provided in the sensor unit driving circuit 30 and the electronic unit driving circuit 20. In addition, the pattern portion 70p may extend to the sensor unit driving circuit 30 and be connected to the first semiconductor 71, and the pattern portion 70p may extend to the electronic unit driving circuit 20 and be connected to the second semiconductor 72.

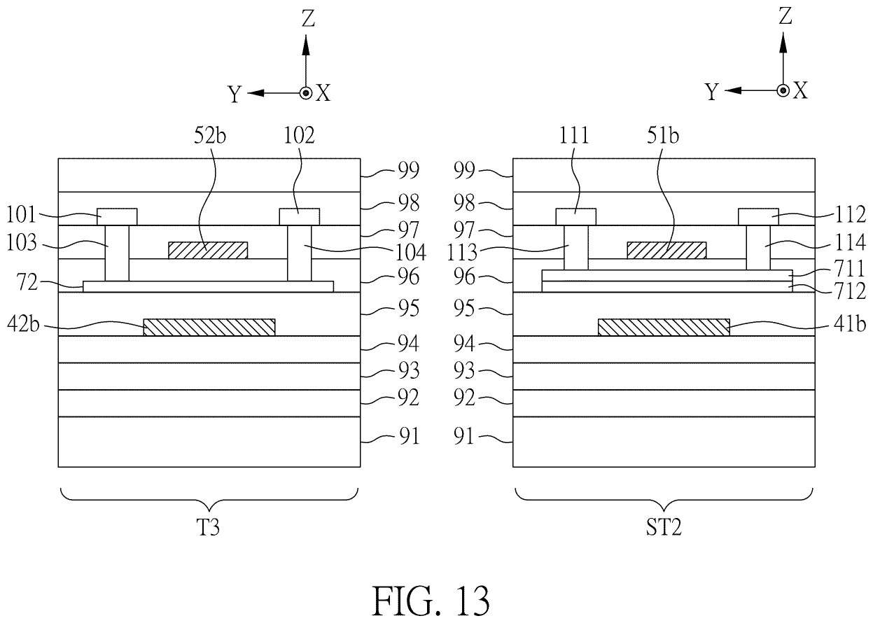

FIG. 12 is a schematic diagram of the layout of the reset transistors T3 and ST2 of the electronic device 1 according to another embodiment of the present disclosure, and please refer to FIG. 1 to FIG. 11 at the same time. In order to make the features clear, FIG. 12 only shows the layout of the reset transistors T3 and ST2, while the layout of the other transistors may refer to the exemplary content of FIG. 6.

As shown in FIG. 11, the semiconductor layer 70 may include a pattern portion 70p, and the first semiconductor 71 of the reset transistor ST2 and the second semiconductor 72 of the reset transistor T3 may share the pattern portion 70p. In one embodiment, the reset transistor ST2 and the reset transistor T3 may share the same end, such as the source, and the other ends (such as the drains) of the reset transistor ST2 and the reset transistor T3 are respectively provided in the sensor unit driving circuit 30 and the electronic unit driving circuit 20. In addition, a portion of the pattern portion 70p may extend in the sensor unit driving circuit 30 to form the first semiconductor 71, and a portion of the pattern portion 70p may extend in the electronic unit driving circuit 20 to form the second semiconductor 72, so that the reset transistor ST2 and reset transistor T3 may share the same channel.

Accordingly, various layouts of the reset transistors T3 and ST2 can be understood, while the present disclosure is not limited thereto.

Next, the structures of the reset transistors T3 and ST2 will be described.

FIG. 13 is a cross-sectional view of reset transistors T3 and ST2 according to an embodiment of the present disclosure, wherein the left half is used to present at least a portion of the cross-sectional structure of the reset transistor T3, and the right half is used to present at least a portion of the cross-sectional structure of the reset transistor ST2.

As shown in FIG. 13, the electronic device 1 may include multiple insulating layers, such as insulating layers 91˜99. The electronic device 1 may also include a drain 101 and a source 102. The positions of the drain 101 and the source 102 in FIG. 13 are only examples and, in fact, the positions of the two may also be interchanged. In addition, the electronic device 1 may also include a drain 111 and a source 112. The positions of the drain 111 and the source 112 in FIG. 13 are only examples and, in fact, the positions of the two may also be interchanged. In addition, the first semiconductor 71 may include a first sub-layer 711 and a second sub-layer 712.

Regarding the reset transistor T3, in one embodiment, in the Z direction, the insulating layer 92 may be disposed on the insulating layer 91, the insulating layer 93 may be disposed on the insulating layer 92, the insulating layer 94 may be disposed on the insulating layer 93, the gate 42b and the insulating layer 95 may be disposed on the insulating layer 94, the second semiconductor 72 and the insulating layer 96 may be disposed on the gate 42b and the insulating layer 95, the gate 52b and the insulating layer 97 may be disposed on the second semiconductor 72 and the insulating layer 96, the drain 101, the source 102 and the insulating layer 98 may be disposed on the gate 52b and the insulating layer 97, and the insulating layer 99 may be disposed on the drain 101, the source 102 and the insulating layer 98. In addition, the drain 101 may be electrically connected to the second semiconductor 72 through a conductive material 103, and the source 102 may be electrically connected to the second semiconductor 72 through a conductive material 104.

Regarding the reset transistor ST2, in one embodiment, in the Z direction, the gate 41b and the insulating layer 95 may be disposed on the insulating layer 94, the first sub-layer 711 of the first semiconductor 71, the second sub-layer 712 of the first semiconductor 71 and the insulating layer 96 may be disposed on the gate 41b and the insulating layer 95, wherein the second sub-layer 712 may be disposed on the first sub-layer 711, the gate 51b and the insulating layer 97 may be disposed on the first sub-layer 711, the second sub-layer 712 and the insulating layer 96, the drain 111, the source 112 and the insulating layer 98 may be disposed on the gate 51b and the insulating layer 97, and the insulating layer 99 may be disposed on the drain 111, the source 112 and the insulating layer 98. In addition, the drain 111 may be electrically connected to the second sub-layer 712 through a conductive material 113, and the source 112 may be electrically connected to the second sub-layer 712 through a conductive material 114.

In one embodiment, the material of the first semiconductor 71 and the second semiconductor 72 may include IGZO, wherein the electron mobility of the first sub-layer 711 of the first semiconductor 71 is higher than the electron mobility of the second sub-layer 712, while it is not limited thereto. In one embodiment, the electron mobility of the first sub-layer 711 of the first semiconductor 71 is higher than the electron mobility of the second semiconductor 72, while it is not limited thereto.

In addition, in one embodiment, compared to the example of FIG. 13, the first semiconductor 71 may also be adjusted to include another second sub-layer 712 (not shown), wherein, in the Z direction, the first sub-layer 711 may be disposed between the two second sub-layers 712. The electron mobility of the first sub-layer 711 may be higher than the electron mobility of the two second sub-layers 712.

In addition, in one embodiment, compared to the example of FIG. 13, the first semiconductor 71 may also be adjusted so that, in the Z direction, the first sub-layer 711 with higher electron mobility is disposed on the second sub-layer 712 with lower electron mobility.

Furthermore, in one embodiment, according to requirements, the second semiconductor 72 may also have multiple sub-layers similar to the aforementioned first semiconductor 71, and the electron mobility of the multiple sub-layers may be different. Alternatively, it may also be designed such that the second semiconductor 72 has multiple sub-layers and the first semiconductor 71 has a single layer.

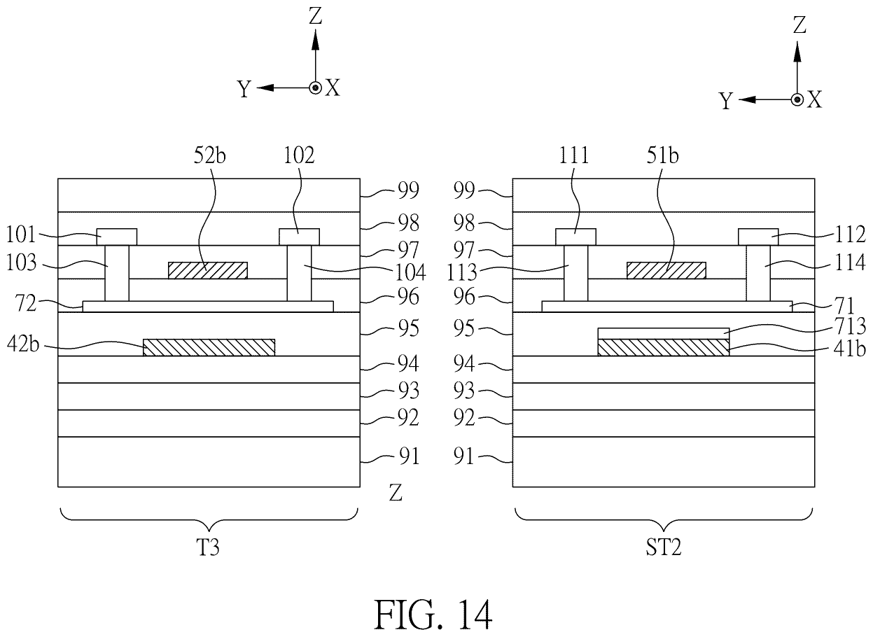

FIG. 14 is a cross-sectional view of the reset transistors T3 and ST2 according to another embodiment of the present application, wherein some features of FIG. 14 may be applicable to the description of FIG. 13, and thus the following description will mainly focus on the differences.

As shown in FIG. 14, the reset transistor ST2 may further include an oxide auxiliary semiconductor layer 713. In one embodiment, in the Z direction, the gate 41b, the oxide auxiliary semiconductor layer 713 and the insulating layer 95 may be disposed on the insulating layer 94, wherein the oxide auxiliary semiconductor layer 713 may be disposed on the insulating layer 95, the first semiconductor 71 and the insulating layer 96 may be disposed on the gate 41b, the oxide auxiliary semiconductor layer 713 and the insulating layer 95.

In one embodiment, in the Z direction, the oxide auxiliary semiconductor layer 713 has a thickness d1, the first semiconductor 71 has a thickness d2, wherein the thickness d1 of the oxide auxiliary semiconductor layer 713 may be smaller than the thickness d2 of the first semiconductor 71 (d1<d2), while it is not limited thereto. In one embodiment, the oxide component (for example, concentration) of the oxide auxiliary semiconductor layer 713 may be smaller than the oxide component of the first semiconductor 71, but it is not limited thereto. The oxide auxiliary semiconductor layer 713 may supplement oxygen vacancies to the first semiconductor 71 so that the threshold voltage of the reset transistor ST2 may be more accurate, thereby reducing leakage current.

In one embodiment, compared to the example of FIG. 14, the oxide auxiliary semiconductor layer 713 may also be adjusted to be disposed at the gate 51b, for example, disposed below the gate 51b in the Z direction, but it is not limited thereto.

In one embodiment, according to requirements, it may also be designed that the second semiconductor 72 has an oxide auxiliary semiconductor layer and the first semiconductor 71 does not have an oxide auxiliary semiconductor layer.

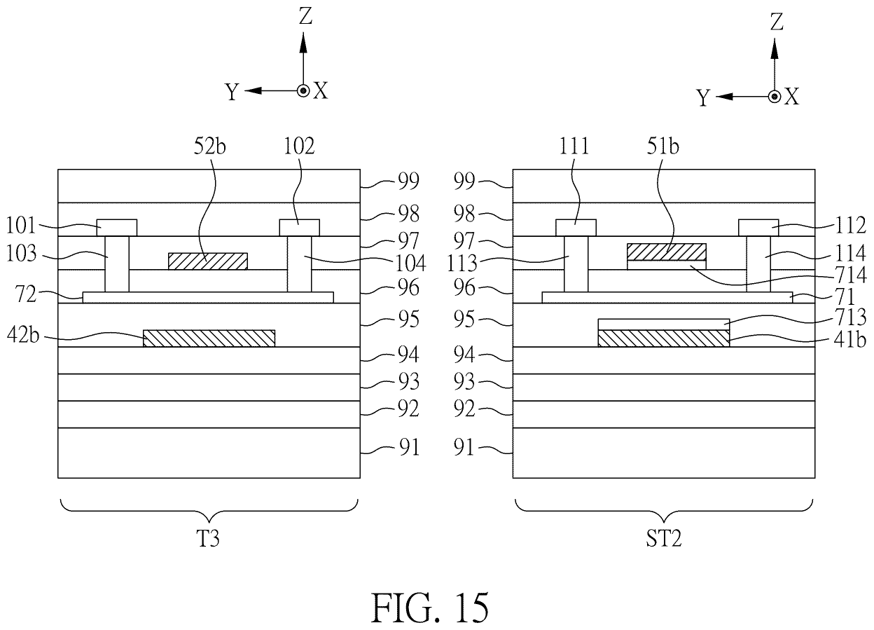

FIG. 15 is a cross-sectional view of reset transistors T3 and ST2 according to another embodiment of the present disclosure, wherein some features of FIG. 15 may be applicable to the description of FIG. 14, and thus the following description will mainly focus on the differences.

As shown in FIG. 15, the electronic device 1 may further include another oxide auxiliary semiconductor layer 714. In the Z direction, the oxide auxiliary semiconductor layer 713 may be disposed above the gate 41b to face upward the first semiconductor 71, and the oxide auxiliary semiconductor layer 714 may be disposed below the gate 51 to face downward the first semiconductor 71. As a result, the threshold voltage of the reset transistor ST2 may be more accurate.

In one embodiment, according to requirements, it may also be designed that the second semiconductor 72 has an oxide auxiliary semiconductor layer and the first semiconductor 71 does not have an oxide auxiliary semiconductor layer.

Accordingly, the structures of the reset transistors T3 and ST2 may be understood, while the present disclosure is not limited to the above implementation aspects.

The electronic device 1 of the present disclosure may also have different circuit structures. For example, the data line DL and the data readout line RL may be integrated together. For example, the same signal line may be used to transmit data signals or sensing signals.

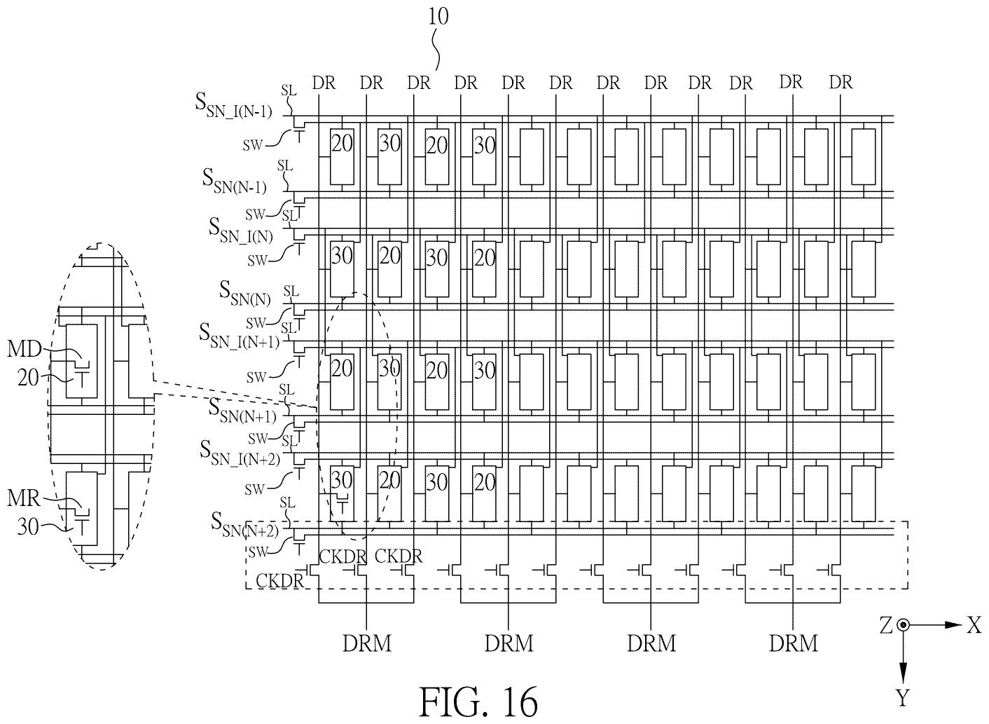

FIG. 16 is a schematic diagram of the circuit structure of the electronic device 1 according to another embodiment of the present disclosure, and please refer to FIG. 1 to FIG. 15 at the same time.

As shown in FIG. 16, the electronic device 1 may include multiple array units p, and each array unit p may be, for example, an electronic unit driving circuit 20 or a sensor unit driving circuit 30.

The electronic device 1 may also include multiple gate lines SL, and each gate line SL may be used to transmit a driving signal, wherein a portion of the driving signals, such as driving signals S_{SN_I(N-1)}, S_{SN_I(N)}, S_{SN_I(N+1)}, S_{SN_I(N+2)}, etc., may be used to drive the IGZO transistors in the electronic unit driving circuit 20 or the sensor unit driving circuit 30, but it is not limited thereto, and another portion of the driving signals, such as S_{SN(N-1)}, S_{SN(N)}, S_{SN(N+1)}, S_{SN(N+2)}, etc., may be used to drive the LTPS transistors in the electronic unit driving circuit 20 or the sensor unit driving circuit 30, but it is not limited thereto. In one embodiment, each scan line SL may be electrically connected to one of the electronic unit driving circuits 20 and one of the sensor unit driving circuits 30 through one end of a transistor SW. For example, the scan line SL may be electrically connected to a first end of the transistor SW, the first end of the transistor SW may be further electrically connected to one of the electronic unit driving circuit 20 and the sensor unit driving circuit 30, and the second end of the transistor SW may be electrically connected to the other one of the electronic unit driving circuit 20 and the sensor unit driving circuit 30, thereby controlling the transmission of the driving signal to the electronic unit driving circuit 20 or the sensor unit driving circuit 30 through turning the transistor SW on or off, while it is not limited thereto.

The electronic device 1 may also include multiple integrated signal lines DR. Each integrated signal line DR may be used to transmit the data signal Data to the electronic unit driving circuit 20, and may be used to transmit the sensing signal from the sensor unit driving circuit 30. Therefore, each integrated signal line DR may be electrically connected to multiple electronic unit driving circuits 20 and sensor unit driving circuits 30. In one embodiment, each integrated signal line DR may be electrically connected to a first end (such as a drain/source) of a transistor CKDR, and the other end (such as a source/drain) of the transistor CKDR may be electrically connected to an integrated control end DRM, whereby, when the transistor CKDR is turned on, the data signal Data provided by the integrated control end DRM may be transmitted to the electronic unit driving circuit 20 through the transistor CKDR, or the sensing signal transmitted by the sensor unit driving circuit 30 may be transmitted to the integrated control end DRM through the integrated signal line DR and the transistor CKDR, while it is not limited thereto.

In addition, in one embodiment, the electronic unit driving circuit 20 may include a transistor MD, and the sensor unit driving circuit 30 may include a transistor MR, wherein one end of the transistor MD (such as drain or source) and one end of the transistor MR (such as drain or source) may be electrically connected to the integrated signal line DR, respectively. Therefore, in the display mode, the transistor MD may be turned on so that the electronic unit driving circuit 20 may receive the data signal Data from the integrated signal line DR, and the transistor MR may be turned off so that the sensor unit driving circuit 30 does not receive the data signal Data. In the sensing mode, the transistor MR may be turned on so that the sensor unit driving circuit 30 may transmit the sensing signal through the integrated signal line DR, and the transistor MD may be turned off so that the electronic unit driving circuit 20 does not receive the sensing signal. As a result, the design of integrating the data line DL and the data readout line RL can be realized. In one embodiment, the material of the transistor MD or MR may include LTPS, IGZO or HoMnO3 (HMO), but it is not limited thereto.

In addition, in one embodiment, multiple integrated signal lines DR may share one integrated control end DRM. For example, the integrated control end DRM may include a multiplexer (not shown) to be simultaneously in electrical connection with multiple integrated signal lines DR. In one embodiment, three integrated signal lines DR may share one integrated control end DRM, but it is not limited thereto. In one embodiment, the operation timing of each integrated control end DRM may be staggered through timing control, but it is not limited thereto. In one embodiment, each integrated control end DRM may include at least one transistor (not shown), and the material of the at least one transistor may include LTPS or HMO, while it is not limited thereto.

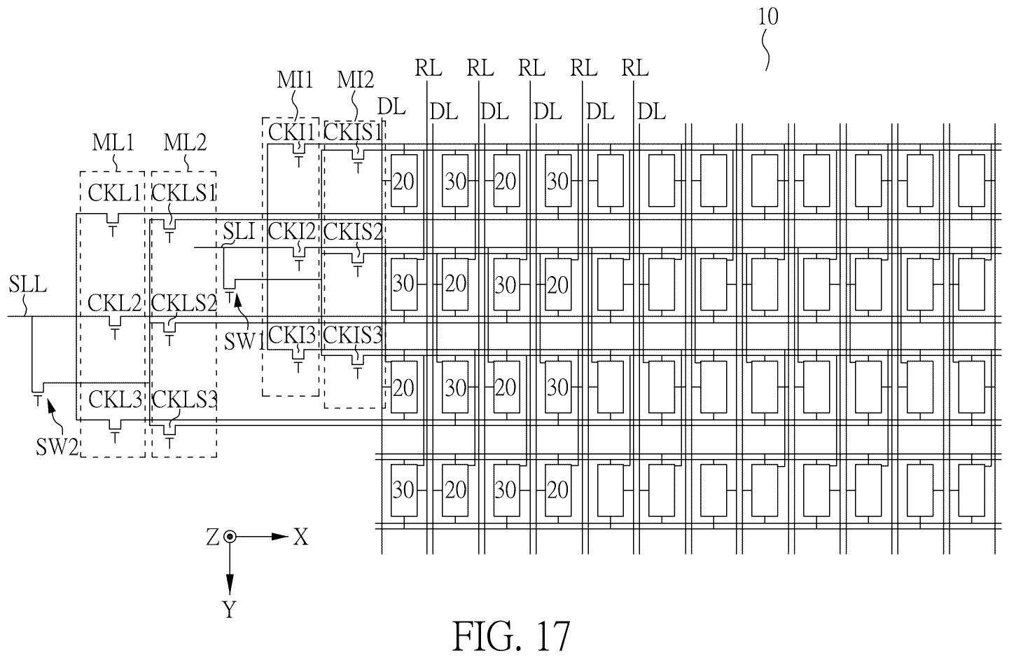

FIG. 17 is a schematic diagram of the circuit structure of the electronic device 1 according to another embodiment of the present disclosure, wherein some features of the example in FIG. 17 may be applicable to the description of the example in FIG. 16, and thus the following description mainly focuses on the differences.

As shown in FIG. 17, each gate line SL of the electronic device 1 may be electrically connected to multiple electronic unit driving circuits 20 and sensor unit driving circuits 30 through multiplexing. For example, the gate line SLI corresponding to IGZO transistor may be electrically connected to multiple electronic unit driving circuits 20 through a multiplexer MI1, and may be electrically connected to multiple sensor unit driving circuits 30 through a multiplexer MI2. The gate line SLL corresponding to the LTPS transistor may be electrically connected to multiple electronic unit driving circuits 20 through a multiplexer ML1, and may be electrically connected to multiple sensor unit driving circuits 30 through a multiplexer ML2.

In one embodiment, each gate line SL_I corresponding to the IGZO transistor may be electrically connected to the first end (such as drain or source) of a transistor SW1 and the multiplexer MI1, and the second end of the transistor SW1 may be electrically connected to the multiplexer MI2, so that, by turning the transistor SW1 on or off, it is able to determine whether the driving signal transmitted by the gate line SLI enters the multiplexer MI1 or the multiplexer MI2, thereby driving the electronic unit driving circuit 20 or the sensor unit driving circuit 30, while it is not limited thereto. In one embodiment, the multiplexer MI1 may include multiple transistors (such as CKI1, CKI2 and CKI3, but it is not limited thereto), which are respectively electrically connected to different electronic unit driving circuits 20. In one embodiment, the multiplexer MI2 may include multiple transistors (such as CKIS1, CKIS2 and CKIS3, but it is not limited thereto), which are respectively electrically connected to different sensor unit driving circuits 30.

In one embodiment, each gate line SLL corresponding to the LTPS transistor may be electrically connected to the first end (such as drain or source) of a transistor SW2 and the multiplexer ML1, and the second end of the transistor SW2 (such as source or drain) may be electrically connected to the multiplexer ML2, so that, by turning the transistor SW2 on or off, it is able to determine whether the driving signal transmitted by the gate line SLL enters the multiplexer ML1 or the multiplexer ML2, thereby driving the electronic unit driving circuit 20 or the sensor unit driving circuit 30, while it is not limited thereto. In one embodiment, the multiplexer ML1 may include multiple transistors (such as CKL1, CKL2 and CKL3, but it is not limited thereto), which are respectively electrically connected to different electronic unit driving circuits 20. In one embodiment, the multiplexer ML2 may include multiple transistors (such as CKLS1, CKLS2 and CKLS3, but it is not limited thereto), which are respectively electrically connected to different sensor unit driving circuits 30.

In one embodiment, the material of the transistor SW1 or SW2 may include LTPS, IGZO or HMO, while it is not limited thereto. In one embodiment, the multiplexer MI1, MI2, ML1 or ML2 may include multiple transistors, and the material of the transistors may include LTPS or HMO, while it is not limited thereto.

In addition, in this embodiment, the electronic unit driving circuit 20 may be electrically connected to the data line DL, and the sensor unit driving circuit 30 may be electrically connected to the data readout line RL. However, in other embodiments, the structure of FIG. 16 may also be used to integrate the data line DL and the data readout line RL into an integrated signal line DR, but it is not limited thereto.

Accordingly, various implementation aspects of the circuit structure of the electronic device 1 of the present disclosure can be understood. It is noted that the present disclosure is not limited thereto.

In one embodiment, it may determine whether the product in contention falls within the protection scope of the present disclosure at least based on the presence or absence of components, component configuration, mechanical observation and/or operation mode, while it is not limited thereto.

The details or features of the various embodiments of the present disclosure may be mixed and matched as long as they do not violate or conflict the spirit of the disclosure.

Accordingly, the present disclosure may provide an electronic device with display function and sensing function. Since the display circuit and the sensor circuit may be integrated together, the electronic device of the present disclosure may provide high-resolution display function and high-definition sensing function.

The aforementioned specific embodiments should be construed as merely illustrative, and not limiting the rest of the present disclosure in any way.

1. An electronic device, comprising:
a substrate;
a first conductive layer disposed on the substrate and provided with a first gate and a line segment, wherein the line segment is connected to the first gate;
an electronic unit and a sensor unit respectively disposed on the substrate; and
a sensor unit driving circuit disposed on the substrate and electrically connected to the electronic unit and the sensor unit,
wherein the sensor unit driving circuit includes a first transistor, the first transistor has the first gate, and a shape of the first gate is different from a shape of the line segment.

2. The electronic device as claimed in claim 1, wherein the shape of the first gate being different from the shape of the line segment indicates that a width of the first gate is different from a width of the line segment.

3. The electronic device as claimed in claim 2, wherein a ratio of the width of the line segment to the width of the first gate satisfies an equation: (0.3 times the width of the first gate)<the ratio<(0.7 times the width of the first gate).

4. The electronic device as claimed in claim 1, further comprising a semiconductor layer and an electronic unit driving circuit respectively disposed on the substrate, the electronic unit driving circuit including a second transistor electrically connected to the electronic unit, wherein the semiconductor layer includes a pattern portion, the first transistor includes a first semiconductor, the second transistor includes a second semiconductor, and the first semiconductor and the second semiconductor shares the pattern portion.

5. The electronic device as claimed in claim 4, wherein a material of the semiconductor layer includes metal oxide.

6. The electronic device as claimed in claim 1, further comprising a second conductive layer disposed on the first conductive layer, wherein the second conductive layer includes a second gate, the first transistor has the second gate, and the second gate of the first transistor at least partially overlaps the first gate of the first transistor.

7. The electronic device as claimed in claim 6, wherein a shape of the first gate is different from a shape of the second gate.

8. The electronic device as claimed in claim 7, wherein the shape of the first gate being different from the shape of the second gate indicates that a width of the first gate is different from a width of the second gate.

9. The electronic device as claimed in claim 1, further comprising an electronic unit driving circuit disposed on the substrate, wherein the first conductive layer includes a second gate, the electronic unit driving circuit includes a second transistor, the second transistor has the second gate, and a shape of the second gate is different from the shape of the line segment.

10. The electronic device as claimed in claim 9, further comprising a third transistor disposed on the substrate, wherein the electronic device further includes an active area and a peripheral area, the peripheral area is adjacent to the active area, the sensor unit driving circuit and the electronic unit driving circuit are disposed in the active area, the third transistor is disposed in the peripheral area, and the third transistor controls a signal to the first transistor and the second transistor.

11. The electronic device as claimed in claim 10, further comprising a fourth transistor disposed on the substrate, wherein the fourth transistor is electrically connected between the first transistor and the second transistor, and the signal is transmitted to the first transistor through a fourth transistor.

12. The electronic device as claimed in claim 9, wherein the line segment is connected to the second gate.

13. The electronic device as claimed in claim 1, further comprising an electronic unit driving circuit disposed on the substrate, the electronic unit driving circuit including a second transistor electrically connected to the electronic unit, wherein the electronic device further includes a third transistor and a fourth transistor respectively disposed on the substrate, wherein the electronic device further includes an active area and a peripheral area, the sensor unit driving circuit and the electronic unit driving circuit are disposed in the active area, the third transistor and the fourth transistor are disposed in the peripheral area, the third transistor controls a first signal to the first transistor, and the fourth transistor controls a second signal to the second transistor.

14. The electronic device as claimed in claim 13, wherein the first signal is a reset signal, and the second signal is a switch signal.

15. The electronic device as claimed in claim 14, further comprising a fifth transistor disposed on the substrate and located in the peripheral area, wherein the sensor unit driving circuit includes a sixth transistor, the fifth transistor controls a readout signal to the sixth transistor during multiple first turn-on periods, the fourth transistor controls the switch signal to the second transistor during multiple second turn-on periods, and at least one of the multiple first turn-on periods does not overlap at least one of the multiple second turn-on periods.

16. The electronic device as claimed in claim 1, further comprising a second conductive layer and an electronic unit driving circuit respectively disposed on the substrate, wherein the second conductive layer includes a second gate, the electronic unit driving circuit includes a second transistor, the second transistor has the second gate, and the second gate is electrically connected to the electronic unit.

17. The electronic device as claimed in claim 16, wherein a shape of the second gate is different from the shape of the line segment.

18. The electronic device as claimed in claim 17, wherein a shape of the second gate being different from the shape of the line segment indicates that a width of the second gate is smaller than a width of the line segment.

19. The electronic device as claimed in claim 16, wherein the first transistor and the second transistor have semiconductors of different materials.

20. The electronic device as claimed in claim 16, further comprising an additional conductive layer disposed on the substrate, wherein the additional conductive layer includes a connection portion, and the first gate and the second gate are electrically connected through the connection portion.
